(19) United States
(12) Patent Application Publication
(10) Pub. No.: US 2026/0040953 A1
(43) Pub. Date: Feb. 5, 2026

(54) INDUCTIVE DEVICE HAVING MAGNETIC COUPLED INDUCTORS

(71) Applicant: QUALCOMM Incorporated, San Diego, CA (US)

(72) Inventors: Kai LIU, San Diego, CA (US); Jui-Yi CHIU, Taichung City (TW); Jonghae KIM, San Diego, CA (US)

(21) Appl. No.: 18/789,871

(22) Filed: Jul. 31, 2024

(51) Int. Cl. H01L 23/64; H01L 23/00; H01L 23/498

(52) U.S. Cl. CPC H01L 23/645; H01L 23/49816; H01L 23/49822; H01L 23/49838; H01L 23/49866; H01L 24/16; H01L 2224/16225; H01L 2924/19011; H01L 2924/19042

(57) ABSTRACT

Disclosed are techniques for a structure of an inductive device. In an aspect, an inductive device includes a first set of conductive patterns and a second set of conductive patterns alternatively arranged in a first array; a third set of conductive patterns and a fourth set of conductive patterns alternatively arranged in a second array; a first set of conductive structures configured to connect the first set of conductive patterns and the third set of conductive patterns to form a first coil structure; a second set of conductive structures configured to connect the second set of conductive patterns and the fourth set of conductive patterns to form a second coil structure; and a interconnect configured to connect a first conductive structure of the first set of conductive structures to a second conductive structure of the second set of conductive structures.

### TECHNICAL FIELD

The present disclosure generally relates to an inductive device, and, more particularly, to an inductive device that includes magnetic coupled inductors (MCI).

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via conductive paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-die devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth, and other communications), and the like.

In some applications, an IC package may be further mounted on a circuit board (e.g., a printed circuit board, or known as a PCB) of an electronic device. In some examples, a power management integrated circuit (PMIC) (e.g., in the form of another IC package) may be mounted on the PCB and configured to manage one or more power distribution networks (PDNs) for supplying power to the IC dies in the IC package. In some applications, the PMIC is configured to receive an external power supply at a higher voltage level (e.g., 5˜12 volts (V)) to an internal supply voltage at a lower voltage level (0.7˜1.0 V or 1.5˜2.5 V) for energizing the IC die(s) in the IC package.

In some applications, one or more passive devices may be electrically coupled to a conductive path carrying the internal supply voltage or an output voltage of a PMIC. In some examples, one or more capacitive devices may be electrically coupled to the conductive path carrying the internal supply voltage (e.g., between the conductive path carrying the internal supply voltage and another conductive path carrying a ground voltage) in order to stabilize a direct current (DC) voltage level of the internal supply voltage. In some examples, one or more inductive devices may be electrically coupled to the conductive path carrying the internal supply voltage (e.g., connected to the conductive path in series) in order to reduce the non-DC noises of (or coupled to by cross-talking) the internal supply voltage. In some examples, these passive devices may be implemented as discrete components (e.g., such as surface mounted devices (SMDs) in their own packages) disposed on the PCB or as embedded devices disposed in the package of the PMIC. In some configurations, the one or more inductive devices may include an inductive device that includes at least two magnetic coupled inductors that may be usable at an output stage of a DC converter of the PMIC.

Accordingly, to further improve the performance and reduce the cost of an electronic device, there may be a need for an inductive device, which includes magnetic coupled inductors usable in conjunction with an PMIC in the electronic device, with a suitable inductance, an increased magnetic coupling coefficient, and/or a reduced DC resistance, together with reduced manufacturing complexity and/or costs.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an inductive device includes a first array of conductive patterns arranged in parallel at a first metallization layer, the first array of conductive patterns including a first set of conductive patterns and a second set of conductive patterns that are alternatively arranged in the first array; a second array of conductive patterns arranged in parallel at a second metallization layer, the second array of conductive patterns including a third set of conductive patterns and a fourth set of conductive patterns that are alternatively arranged in the second array; a first set of conductive structures and a second set of conductive structures at an intermediate layer between the first metallization layer and the second metallization layer, the first set of conductive structures configured to connect the first set of conductive patterns and the third set of conductive patterns to form a first coil structure of a first inductor of the inductive device, and the second set of conductive structures configured to connect the second set of conductive patterns and the fourth set of conductive patterns to form a second coil structure of a second inductor of the inductive device; and a first interconnect at the intermediate layer and configured to connect a first conductive structure of the first set of conductive structures to a second conductive structure of the second set of conductive structures.

In an aspect, a method of manufacturing an inductive device includes forming a first array of conductive patterns arranged in parallel at a first metallization layer, the first array of conductive patterns including a first set of conductive patterns and a second set of conductive patterns that are alternatively arranged in the first array; forming a second array of conductive patterns arranged in parallel at a second metallization layer, the second array of conductive patterns including a third set of conductive patterns and a fourth set of conductive patterns that are alternatively arranged in the second array; forming a first set of conductive structures and a second set of conductive structures at an intermediate layer between the first metallization layer and the second metallization layer, the first set of conductive structures configured to connect the first set of conductive patterns and the third set of conductive patterns to form a first coil structure of a first inductor of the inductive device, and the second set of conductive structures configured to connect the second set of conductive patterns and the fourth set of conductive patterns to form a second coil structure of a second inductor of the inductive device; and forming a first interconnect at the intermediate layer and configured to connect a first conductive structure of the first set of conductive structures to a second conductive structure of the second set of conductive structures.

In an aspect, an electronic device includes an inductive device that comprises: a first array of conductive patterns arranged in parallel at a first metallization layer, the first array of conductive patterns including a first set of conductive patterns and a second set of conductive patterns that are alternatively arranged in the first array; a second array of conductive patterns arranged in parallel at a second metallization layer, the second array of conductive patterns including a third set of conductive patterns and a fourth set of conductive patterns that are alternatively arranged in the second array; a first set of conductive structures and a second set of conductive structures at an intermediate layer between the first metallization layer and the second metallization layer, the first set of conductive structures configured to connect the first set of conductive patterns and the third set of conductive patterns to form a first coil structure of a first inductor of the inductive device, and the second set of conductive structures configured to connect the second set of conductive patterns and the fourth set of conductive patterns to form a second coil structure of a second inductor of the inductive device; and a first interconnect at the intermediate layer and configured to connect a first conductive structure of the first set of conductive structures to a second conductive structure of the second set of conductive structures.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 is a cross-sectional view of a portion of a circuit board assembly example, according to aspects of the disclosure.

FIG. 2A is a circuit diagram of an example inductive device that includes two magnetic coupled inductors, according to aspects of the disclosure.

FIG. 2B is a simplified perspective view of a portion of the example inductive device, according to aspects of the disclosure.

FIG. 2C is a simplified top view of a portion of the example inductive device, according to aspects of the disclosure.

FIG. 3A is a simplified cross-sectional view of a portion of an IC package that includes the example inductive device, according to aspects of the disclosure.

FIG. 3B is a simplified cross-sectional view of another portion of the IC package corresponding to the reference line A-A′ of FIG. 2C, according to aspects of the disclosure.

FIG. 4A is a circuit diagram of an inductive device based on a first example variation, according to aspects of the disclosure.

FIG. 4B is a simplified perspective view of a portion of the inductive device based on the first example variation, according to aspects of the disclosure.

FIG. 4C is a simplified top view of a portion of the inductive device based on the first example variation, according to aspects of the disclosure.

FIG. 4D is a simplified cross-sectional view of a portion of an IC package that includes the inductive device based on the first example variation, according to aspects of the disclosure.

FIG. 5A is a circuit diagram of an inductive device based on a second example variation, according to aspects of the disclosure.

FIG. 5B is a simplified top view of a portion of the inductive device based on the second example variation, according to aspects of the disclosure.

FIG. 6A is a circuit diagram of an inductive device based on a third example variation, according to aspects of the disclosure.

FIG. 6B is a simplified top view of a portion of the inductive device based on the third example variation, according to aspects of the disclosure.

FIG. 7A is a circuit diagram of an inductive device based on a fourth example variation, according to aspects of the disclosure.

FIG. 7B is a simplified top view of a portion of the inductive device based on the fourth example variation, according to aspects of the disclosure.

FIGS. 8A-8O illustrate structures at various stages of manufacturing an inductive device based on various variations illustrated in FIGS. 4A-7B, according to aspects of the disclosure.

FIG. 9 illustrates a method of manufacturing an inductive device, according to aspects of the disclosure.

FIG. 10 illustrates various electronic devices that may include an inductive device described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to an inductive device including magnetic coupled inductors, and to a method of manufacturing inductive device.

Particular aspects of the subject matter described in this disclosure can be implemented to realize one or more of the following potential advantages. For example, an inductive device may include a first set of conductive patterns and a second set of conductive patterns alternatively arranged in a first array; a third set of conductive patterns and a fourth set of conductive patterns alternatively arranged in a second array; a first set of conductive structures configured to connect the first set of conductive patterns and the third set of conductive patterns to form a first coil structure; and a second set of conductive structures configured to connect the second set of conductive patterns and the fourth set of conductive patterns to form a second coil structure. In some examples, by introducing at least one interconnect at an intermediate layer and configured to connect one of the first set of conductive structures to one of the second set of conductive structures, the resulting inductive device may provide a suitable inductance while further increase the magnetic coupling coefficient and/or reduce the DC resistance, without incurring additional manufacturing complexity and/or costs.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

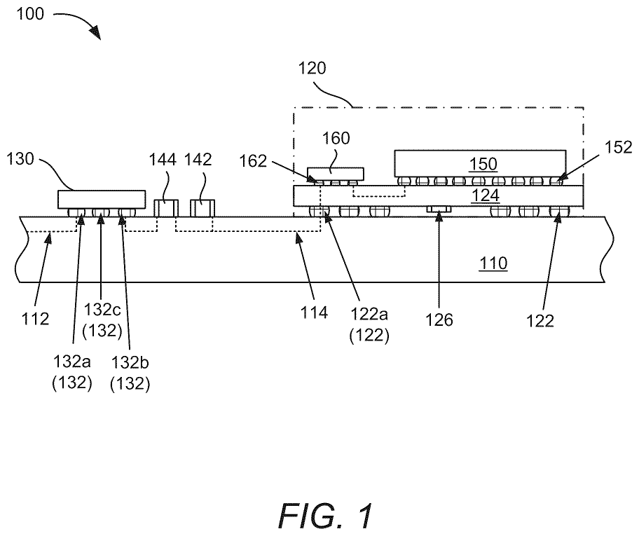

FIG. 1 is a cross-sectional view of a portion of a circuit board assembly example 100, according to aspects of the disclosure. In some aspects, FIG. 1 is a simplified cross-sectional view of the circuit board assembly example 100, and certain details and components of the circuit board assembly example 100 may be simplified or may not be depicted in FIG. 1.

As shown in FIG. 1, the circuit board assembly example 100 may include a printed circuit board (PCB) 110, an integrated circuit (IC) package 120 mounted on the PCB 110, and a power management integrated circuit (PMIC) 130 mounted on the PCB 110. In some aspects, the circuit board assembly example 100 may further include a capacitive device 142 and an inductive device 144 mounted on the PCB 110.

In some aspects, the PCB 110 may include layers of conductive patterns formed therein (not shown). In some aspects, the IC package 120 may be mounted on the PCB 110 through terminal structures 122 (e.g., solder bumps based on a controlled collapse of chip connection (C4) mounting method, also referred to as C4 bumps). In some aspects, the PMIC 130 may be mounted on the PCB 110 through terminal structures 132 (e.g., C4 bumps).

In some aspects, the IC package 120 may include a package substrate 124, a first IC die 150 mounted on an upper surface of the package substrate 124 through terminal structures 152 (e.g., solder bumps or copper pillar bumps), a second IC die 160 mounted on the upper surface of the package substrate 124 through terminal structures 162 (e.g., solder bumps or copper pillar bumps), and one or more passive devices 126 mounted on a lower surface of the package substrate 124. In some aspects, the first IC die 150 may include circuitry configured as a processor, a system on a chip, a memory, or a combination thereof. In some aspects, the second IC die 160 may include circuitry configured as an integrated voltage regulator (IVR).

In some aspects, the PMIC 130 may include a first power node (e.g., corresponding to the terminal structure 132a of the terminal structures 132) configured to carry a first supply voltage, a second power node (e.g., corresponding to the terminal structure 132b of the terminal structures 132) configured to carry a second supply voltage, and a third power node (e.g., corresponding to the terminal structure 132c of the terminal structures 132) configured to carry a third supply voltage. In some aspects, the first supply voltage may have a first voltage level, the second supply voltage may have a second voltage level different from the first voltage level, and the third supply voltage may have a ground voltage level or a third voltage level different from the first voltage level and the second voltage level. In some aspects, the third supply voltage may be the ground voltage level, the second voltage level may be greater than the ground voltage level and may range from 1.5 V to 2.5 V. In some aspects, the first voltage level may be greater than the second voltage level and may range from 5 V to 12 V.

In some aspects, the PMIC 130 may be configured to receive the first supply voltage at the terminal structure 132a through a conductive path 112 formed by various conductive patterns in the PCB 110. In some aspects, the PMIC 130 may be configured to output the second supply voltage at the terminal structure 132b to a terminal structure 122a of the terminal structures 122 of the IC package 120 through a conductive path 114 formed by various conductive patterns in the PCB 110. In some aspects, the PMIC 130 may be configured to carry the third supply voltage at the terminal structure 132c, which is also electrically shared by another terminal structure of the terminal structures 122 of the IC package 120 through another conductive path (not shown) formed by various conductive patterns in the PCB 110.

In some aspects, the second IC die 160 may be configured as an IVR and configured to receive the second supply voltage through a conductive path formed by various conductive patterns in the package substrate 124 and output a fourth supply voltage to the first IC die 150 through another conductive path formed by various conductive patterns in the package substrate 124. In some aspects, the fourth supply voltage may be greater than the ground voltage level and may range from 0.7 V to 1.0 V. In some aspects, the first IC die 150 may be energized based on a voltage difference between the fourth supply voltage and the third supply voltage (e.g., at the ground voltage level).

In some aspects, the capacitive device 142 and the inductive device 144 may be implemented as individual packages compatible with a form factor of an surface mounted device (SMD). In some aspects, the capacitive device 142 may be electrically coupled to the conductive path 114 carrying the second supply voltage (e.g., between the conductive path 114 carrying the second supply voltage and another conductive path carrying the third supply voltage) in order to stabilize a direct current (DC) voltage level of the second supply voltage. In some examples, the inductive device 144 may be electrically coupled to the conductive path 114 carrying the internal supply voltage (e.g., connected to the conductive path 114 in series) in order to reduce the non-DC noises of (or coupled to by cross-talking) the second supply voltage. In some aspects, one or more capacitive devices may be embedded in the package of the PMIC 130 to supplement or in place of the capacitive device 142. In some aspects, one or more inductive devices may be embedded in the package of the PMIC 130 to supplement or in place of the inductive device 144.

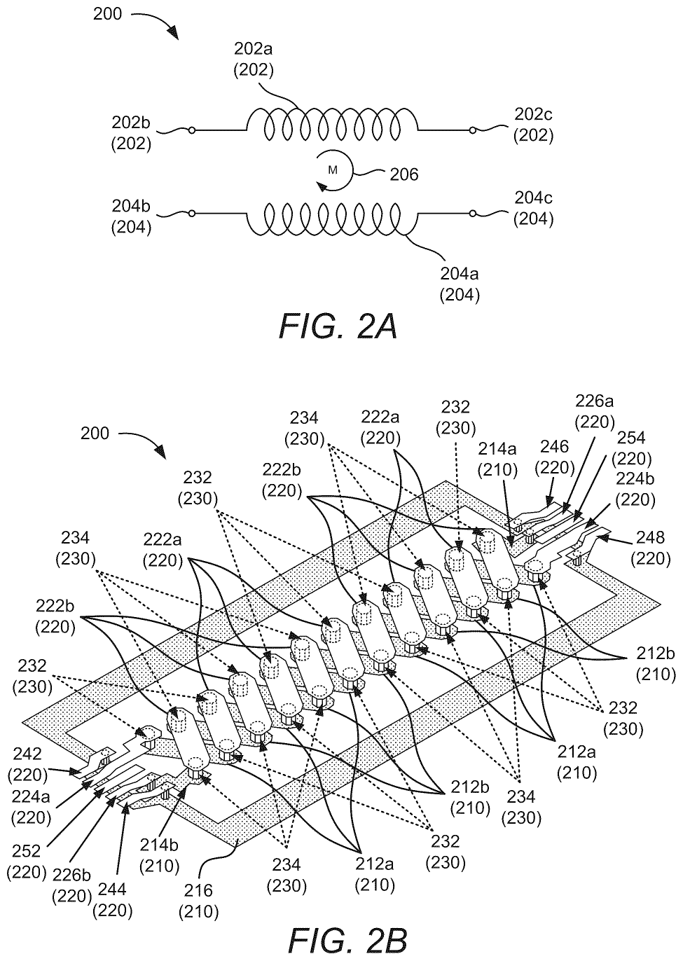

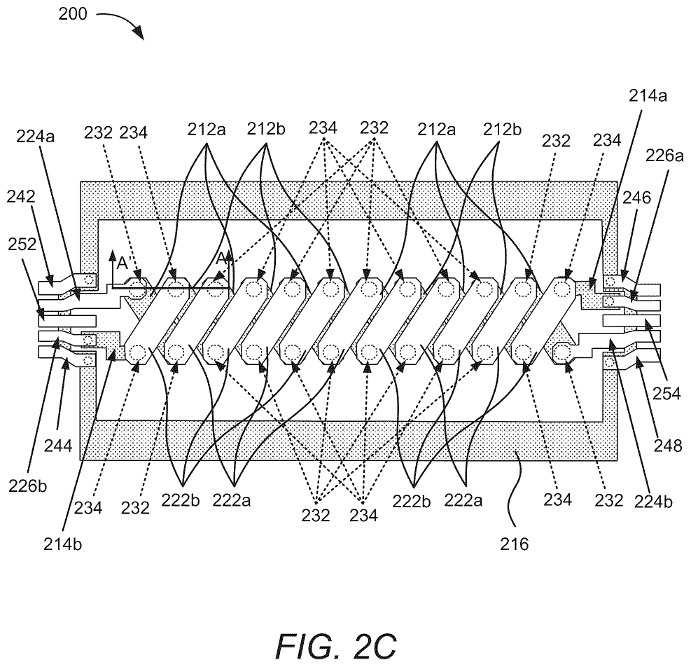

FIG. 2A is a circuit diagram of an example inductive device 200 that includes two magnetic coupled inductors 202 and 204, according to aspects of the disclosure. In some aspects, the inductive device 200 may be usable as a discrete device outside a PMIC (e.g., the inductive device 144 in FIG. 1) or an embedded device inside the package of a PMIC.

As shown in FIG. 2A, the inductive device 200 may include a first inductor 202 having a first coil structure 202a between two terminals 202b and 202c; and a second inductor 204 having a second coil structure 204a between two terminals 204b and 204c. In some aspects, the first inductor 202 and the second inductor 204 may be magnetic coupled (represented by symbol 206). In some aspects, the first inductor 202 and the second inductor 204 may be magnetic coupled based on configuring the first coil structure 202a and the second coil structure 204a as intertwined coils, surrounding a shared magnetic core, or both.

FIG. 2B is a simplified perspective view of a portion of the example inductive device 200, according to aspects of the disclosure. In some aspects, FIG. 2B is a simplified perspective view of the inductive device 200, and certain details and components of the inductive device 200 may be simplified or not depicted in FIG. 2B. In some aspects, to more clearly describe the structure of the inductive device 200, certain features may be depicted as being transparent or not fully depicted in order to reveal one or more other features that may otherwise be visually blocked.

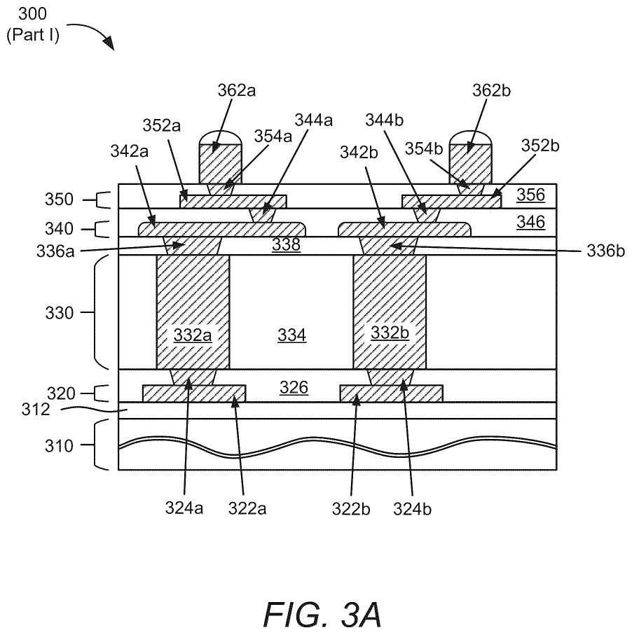

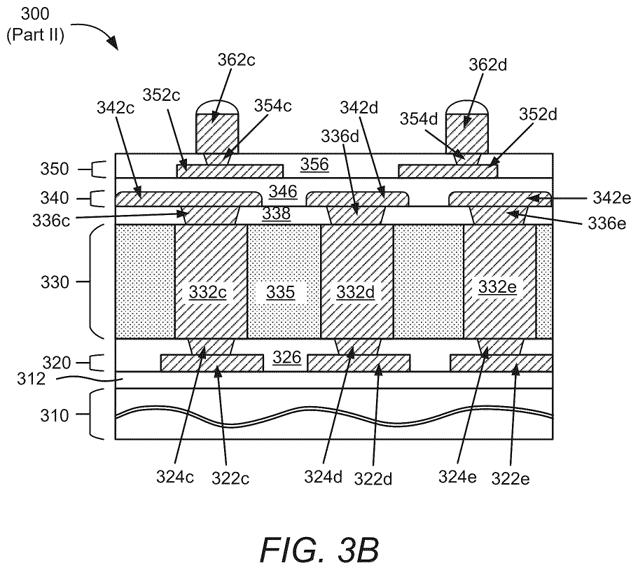

FIG. 2C is a simplified top view of a portion of the example inductive device 200, according to aspects of the disclosure. In some aspects, components in FIG. 2C that are the same or similar to those in FIG. 2B are given the same reference numbers. A simplified cross-sectional view corresponding to the reference line A-A′ will be illustrated in FIG. 3B.

In some aspects, in a case that the inductive device 200 is a discrete device outside a PMIC, the portion depicted in FIGS. 2B and 2C may be disposed on a semiconductor substrate or carrier. In some aspects, in a case that the inductive device 200 is an embedded device inside a PMIC, the portion depicted in FIGS. 2B and 2C may be disposed on a semiconductor substrate with components of PMIC circuitry formed therein. In some aspects, the portion depicted in FIGS. 2B and 2C may have additional metallization layers, dielectric layers, and/or conductive terminals formed thereon.

As shown in FIGS. 2B and 2C, the inductive device 200 may include a first array of conductive patterns (212a and 212b) arranged in parallel at a first metallization layer 210, where the first array of conductive patterns may include a first set of conductive patterns 212a and a second set of conductive patterns 212b that are alternatively arranged in the first array. Also, the inductive device 200 may include a second array of conductive patterns (222a and 222b) arranged in parallel at a second metallization layer 220, where the second array of conductive patterns may include a third set of conductive patterns 222a and a furth set of conductive patterns 222b that are alternatively arranged in the second array. In some aspects, the first array of conductive patterns and the second array of conductive patterns may include a conductive material that includes copper, aluminum, gold, or a combination thereof.

As shown in FIGS. 2B and 2C, the inductive device 200 may include a first set of conductive structures 232 and a second set of conductive structures 234 at an intermediate layer 230 between the first metallization layer 210 and the second metallization layer 220. In some aspects, the first set of conductive structures 232 may connect the first set of conductive patterns 212a and the third set of conductive patterns 222a to form a first coil structure (e.g., 202a in FIG. 2A) of the first inductor (e.g., 202 in FIG. 2A) of the inductive device 200. In some aspects, the second set of conductive structures 234 may connect the second set of conductive patterns 212b and the fourth set of conductive patterns 222b to form a second coil structure (e.g., 204a in FIG. 2A) of the second inductor (e.g., 204 in FIG. 2A) of the inductive device 200. In some aspects, the first set of conductive structures 232 and the second set of conductive structures 234 may include a conductive material that includes copper, aluminum, gold, or a combination thereof.

As shown in FIGS. 2B and 2C, the inductive device 200 may include conductive patterns 214a and 214b at the first metallization layer 210 and conductive patterns 224a, 224b, 226a, and 226b at the second metallization layer 220. In some aspects, the conductive pattern 224a may electrically connected to a first end of the first coil structure through one of the first set of conductive structures 232, the conductive pattern 226a may electrically connected to the conductive pattern 214a through a conductive structure (not labeled) at the intermediate layer 230, and the conductive pattern 214a may electrically connected to a second end of the first coil structure through another one of the first set of conductive structures 232. In some aspects, the conductive pattern 226b may electrically connected to the conductive pattern 214b through a conductive structure (not labeled) at the intermediate layer 230, the conductive pattern 214b may electrically connected to a third end of the second coil structure (corresponding to the first end of the first coil structure) through one of the second set of conductive structures 234, and the conductive pattern 224b may electrically connected to a fourth end of the second coil structure (corresponding to the second end of the first coil structure) through another one of the second set of conductive structures 234. In some aspects, the conductive pattern 224a and the conductive pattern 224b may correspond to the terminals 202b and 202c in FIG. 2A; and the conductive pattern 226b and the conductive pattern 226a may correspond to the terminals 204b and 204c in FIG. 2A.

As shown in FIGS. 2B and 2C, the inductive device 200 may include a conductive pattern 216 at the first metallization layer 210 that surrounds the first set of conductive patterns 212a. In some aspects, the inductive device 200 may further include conductive patterns 242, 244, 246, and 248 at the second metallization layer 220. In some aspects, the conductive patterns 242, 244, 246, and 248 may be electrically coupled to the conductive pattern 216 through respective conductive structures (not labeled) at the intermediate layer 230. In some aspect, the conductive patterns 242, 244, 246, and 248 may be configured to receive a ground reference voltage, such that the conductive pattern 216 may be configured as a shielding structure of the inductive device 200.

In some aspects, the inductive device 200 may further include conductive patterns 252 and 254 at the second metallization layer 220. In some aspects, the conductive patterns 252 and 254 may be electrically floating or electrically coupled to the conductive pattern 216 and/or the conductive patterns 242, 244, 246, and 248.

In some aspects, the inductive device 200 may include a magnetic material (e.g., 335 in FIG. 3B) disposed at the intermediate layer 230 and between the first array of conductive patterns and the second array of conductive patterns. In some aspects, the magnetic material may be configured as a shared magnetic core for the inductors 202 and 204. In some aspects, the magnetic material may include carbon, silicon, chromium, iron, platinum, phosphorus, or any combination thereof.

FIG. 3A is a simplified cross-sectional view of a portion (labeled as (Part I)) of an package 300 (e.g., an IC package or a discrete component package) that includes the example inductive device 200, according to aspects of the disclosure. In some aspects, certain details and components of the package 300 may be simplified or may not be depicted in FIG. 3A.

As shown in FIG. 3A, the package 300 may include a substrate portion 310. In some aspects, in a case that the package 300 corresponds to forming the inductive device as a discrete device, the substrate portion 310 may correspond to a semiconductor substrate or carrier. In some aspects, in a case that the package 300 corresponds to incorporating a PMIC and the inductive device, the substrate portion 310 may include a semiconductor substrate, components of PMIC circuitry formed on the substrate, and one or more metallization layers formed on the components and the semiconductor substrate.

In some aspects, the package 300 may include a first dielectric layer 312 over the substrate portion 310, and one or more conductive patterns 322a and 322b at a first metallization layer 320 over the first dielectric layer 312. In some aspects, the first dielectric layer 312 may include silicon oxide or polyimide. In some aspects, the one or more conductive patterns 322a and 322b may include a conductive material that includes copper, aluminum, gold, or a combination thereof. In some aspects, the one or more conductive patterns 322a and 322b may be configured as a first redistribution layer configured to form conductive paths connecting the circuitry formed in the substrate portion 310 (if any) based on one or more conductive structures (not shown) through the first dielectric layer 312.

In some aspects, the package 300 may include one or more via structures 324a and 324b over the one or more conductive patterns 322a and 322b. In some aspects, the package 300 may include a second dielectric layer 326 over the first dielectric layer 312 and surrounding the one or more conductive patterns 322a and 322b and the one or more via structures 324a and 324b. In some aspects, the second dielectric layer 326 may include silicon oxide or polyimide. In some aspects, the one or more via structures 324a and 324b may include a conductive material that includes copper, aluminum, gold, or a combination thereof.

In some aspects, the package 300 may include one or more pillar structures 332a and 332b at an intermediate layer 330 over the one or more via structures 324a and 324b. In some aspects, the IC package 300 may include a third dielectric layer 334 at the intermediate layer 330, over the second dielectric layer 326, and surrounding the one or more pillar structures 332a and 332b. In some aspects, the third dielectric layer 334 may include silicon oxide or polyimide. In some aspects, the one or more pillar structures 332a and 332b may include a conductive material that includes copper, aluminum, gold, or a combination thereof.

In some aspects, the package 300 may include one or more via structures 336a and 336b over the one or more pillar structures 332a and 332b and the third dielectric layer 334. In some aspects, the IC package 300 may include a fourth dielectric layer 338 over the third dielectric layer 334 and surrounding the one or more via structures 336a and 336b. In some aspects, the fourth dielectric layer 338 may include silicon oxide or polyimide. In some aspects, the one or more via structures 336a and 336b may include a conductive material that includes copper, aluminum, gold, or a combination thereof.

In some aspects, the package 300 may include one or more conductive patterns 342a and 342b at a second metallization layer 340 over the one or more via structures 336a and 336b, the fourth dielectric layer 338, and the intermediate layer 330. In some aspects, the one or more conductive patterns 342a and 342b may include a conductive material that includes copper, aluminum, gold, or a combination thereof. In some aspects, the one or more conductive patterns 342a and 342b may be configured as a second redistribution layer configured to form conductive paths.

In some aspects, the package 300 may include one or more via structures 344a and 344b over the one or more conductive patterns 342a and 342b. In some aspects, the package 300 may include a fifth dielectric layer 346 over the fourth dielectric layer 338 and surrounding the one or more conductive patterns 342a and 342b and the one or more via structures 344a and 344b. In some aspects, the fifth dielectric layer 346 may include silicon oxide or polyimide. In some aspects, the one or more via structures 344a and 344b may include a conductive material that includes copper, aluminum, gold, or a combination thereof.

In some aspects, the package 300 may include one or more conductive patterns 352a and 352b at a third metallization layer 350 over the one or more via structures 346a and 346b and the fifth dielectric layer 346. In some aspects, the package 300 may include one or more via structures 354a and 354b over the one or more conductive patterns 352a and 352b. In some aspects, the one or more conductive patterns 352a and 352b may be configured as a third redistribution layer configured to form conductive paths. In some aspects, the package 300 may include a sixth dielectric layer 356 over the fifth dielectric layer 346 and surrounding the one or more conductive patterns 352a and 352b and the one or more via structures 354a and 354b. In some aspects, the sixth dielectric layer 356 may include silicon oxide or polyimide. In some aspects, the one or more conductive patterns 352a and 352b may include a conductive material that includes copper, aluminum, gold, or a combination thereof. In some aspects, the one or more via structures 354a and 354b may include a conductive material that includes copper, aluminum, gold, or a combination thereof.

In some aspects, the package 300 may further include one or more terminal structures 362a and 362b over the one or more via structures 354a and 354b and the sixth dielectric layer 356. As shown in FIG. 3A, each one of the one or more terminal structures 362a and 362b may be a copper pillar bump that includes a copper pillar and a solder portion over the copper pillar.

FIG. 3B is a simplified cross-sectional view of another portion (labeled as (Part II)) of the package 300 corresponding to the reference line A-A′ of FIG. 2C, according to aspects of the disclosure. The components that are the same or similar to those in FIG. 3A are given the same reference numbers, and the detailed description thereof may be simplified or omitted. As shown in FIG. 3B, the package 300 may further include conductive patterns 322c, 322d, and 322e at the first metallization layer 320; via structures 324c, 324d, and 324c over the conductive patterns 322c, 322d, and 322e; pillar structures 332c, 332d, and 332e at the intermediate layer 330 and over the via structures 324c, 324d, and 324c; via structures 336c, 336d, and 336e over the pillar structures 332c, 332d, and 332c; and conductive patterns 342c, 342d, and 342e at the second metallization layer 340 and over the via structures 336c, 336d, and 336c. As shown in FIG. 3B, the package 300 may further include conductive patterns 352c and 352d at the third metallization layer 350; via structures 354c and 354d over the conductive patterns 352c and 352d; and terminal structures 362c and 362d over the via structures 354c and 354d.

In some aspects, the conductive patterns 322c, 322d, and 322e may correspond to the first array of conductive patterns illustrated in FIGS. 2B and 2C. In some aspects, the conductive patterns 322c and 322e may belong to the first set of conductive patterns 212a, and the conductive pattern 322d may belong to the second set of conductive patterns 212b. In some aspects, the conductive patterns 342d, and 342e may correspond to the second array of conductive patterns illustrated in FIGS. 2B and 2C. In some aspects, the conductive pattern 342e may belong to the third set of conductive patterns 222a, and the conductive pattern 322d may belong to the fourth set of conductive patterns 222b. In some aspects, the conductive pattern 342c may correspond to the conductive pattern 224a illustrated in FIGS. 2B and 2C. In some aspects, the combination of the via structure 324c, the pillar structures 332c, and the via structure 336c may correspond to one of the first set of conductive structures 232; the combination of the via structure 324d, the pillar structures 332d, and the via structure 336d may correspond to one of the second set of conductive structures 234; and the combination of the via structure 324e, the pillar structures 332e, and the via structure 336e may correspond to another one of the first set of conductive structures 232.

As shown in FIG. 3B, compared with the portion shown in FIG. 3A, a magnetic material 335 is disposed at the intermediate layer 330 instead of the third dielectric layer 334. In some aspects, the magnetic material 335 may be configured as a magnetic core for the inductive device 200. In some aspects, the magnetic material 335 may include carbon, silicon, chromium, iron, platinum, phosphorus, or any combination thereof.

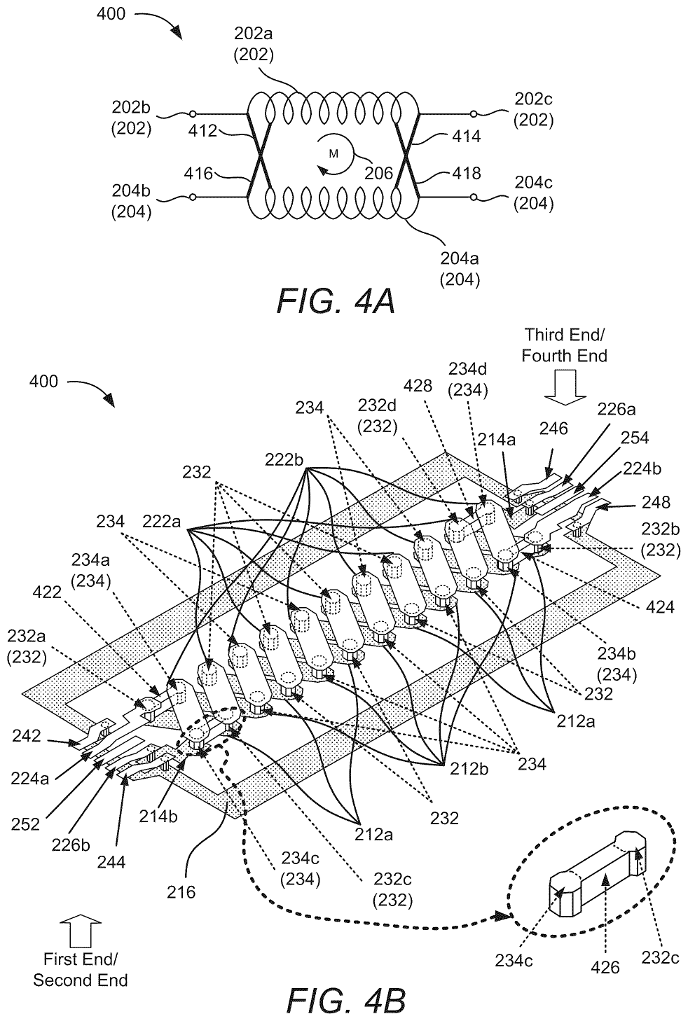

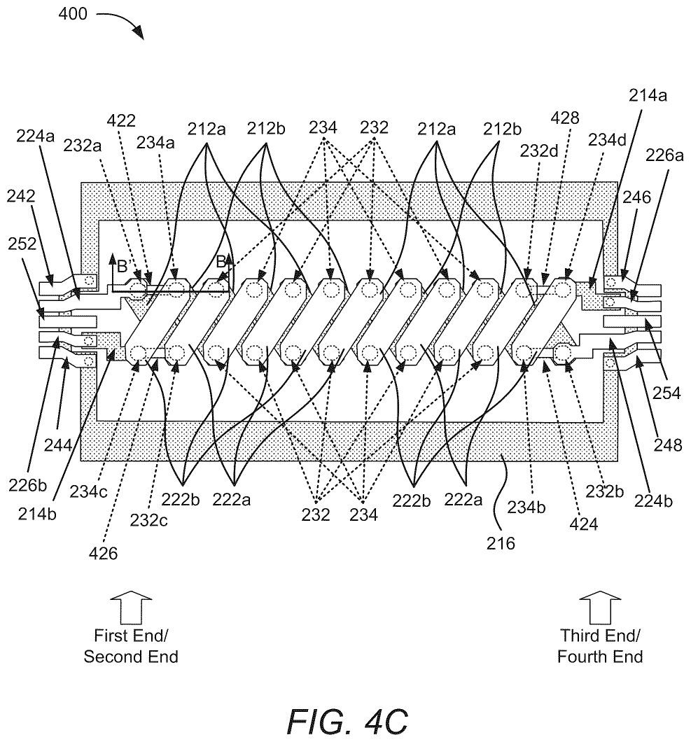

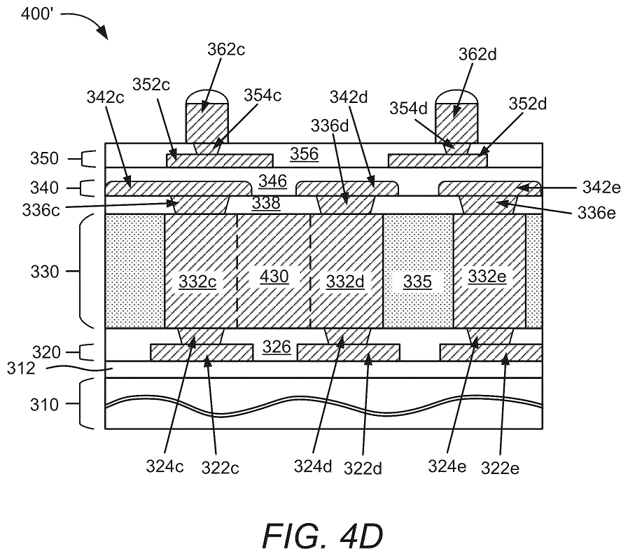

In some aspects, the inductive device 200 as illustrated based on FIGS. 2A-3B may be manufactured based on a process that is less complex with less costs than other types of inductive devices for similar applications, such as a process based on cobalt-zirconium-tantalum (CZT) deposition. In some aspects, different variations (as further illustrated based on FIGS. 4A-7B) may be developed based on the inductive device 200 as illustrated based on FIGS. 2A-3B to provide a suitable inductance, an increased magnetic coupling coefficient, and/or a reduced DC resistance, based on basically the same or similar manufacturing processes and/or costs. In some aspects, the variations illustrated in this disclosure may be based on disposing one or more interconnects at the intermediate layer 330, where the one or more interconnects may electrically connect respective one or more of the first set of conductive structures to respective one or more of the second set of conductive structures.

FIG. 4A is a circuit diagram of an inductive device 400 based on a first example variation of the inductive device 200, according to aspects of the disclosure. In some aspects, the components in FIG. 4A that are the same or similar to those in FIG. 2A are given the same reference numbers, and detailed description thereof may be simplified or omitted.

In some aspects, compared with the inductive device 200, the inductive device 400 may further include interconnects 412, 414, 416, and 418. In some aspects, the interconnect 412 may electrically connect a first end of the first coil structure 202a to a half-turn position of the second coil structure 204a from a second end of the second coil structure 204a corresponding to the first end of the first coil structure 202a. In some aspects, the interconnect 414 may electrically connect a third end of the first coil structure 202a to a half-turn position of the second coil structure 204a from a fourth end of the second coil structure 204a corresponding to the third end of the first coil structure 202a. In some aspects, the interconnect 416 may electrically connect a half-turn position of the first coil structure 202a from the first end of the first coil structure 202a to the second end of the second coil structure 204a. In some aspects, the interconnect 418 may electrically connect a half-turn position of the first coil structure 202a from the third end of the first coil structure 202a to the fourth end of the second coil structure 204a.

FIG. 4B is a simplified perspective view of a portion of the inductive device 400 based on the first example variation, according to aspects of the disclosure. FIG. 4C is a simplified top view of a portion of the inductive device 400 based on the first example variation, according to aspects of the disclosure. In some aspects, components in FIGS. 4B and 4C that are the same or similar to those in FIG. 2B are given the same reference numbers, and detailed description thereof may be simplified or omitted. A simplified cross-sectional view corresponding to the reference line B-B′ will be illustrated in FIG. 4D.

As shown in FIGS. 4B and 4C, the inductive device 400 may include a first interconnect 422 that is configured to connect a first conductive structure 232a of the first set of conductive structures 232 disposed at a first end of the first coil structure to a second conductive structure 234a of the second set of conductive structures 234 disposed at a half-turn position of the second coil structure from a second end of the second coil structure corresponding to the first end of the first coil structure. The inductive device 400 may include a second interconnect 424 that is configured to connect a third conductive structure 232b of the first set of conductive structures 232 disposed at a third end of the first coil structure to a fourth conductive structure 234b of the second set of conductive structures 234 disposed at a half-turn position of the second coil structure from a fourth end of the second coil structure corresponding to the third end of the first coil structure. The inductive device 400 may include a third interconnect 426 that is configured to connect a fifth conductive structure 232c of the first set of conductive structures 232 disposed at a half-turn position of the first coil structure from the first end of the first coil structure to a sixth conductive structure 234c of the second set of conductive structures 234 disposed at the second end of the second coil structure. The inductive device 400 may further include a fourth interconnect 428 that is configured to connect a seventh conductive structure 232d of the first set of conductive structures 232 disposed at a half-turn position of the first coil structure from the third end of the first coil structure to an eighth conductive structure 234d of the second set of conductive structures 234 disposed at the fourth end of the second coil structure.

FIG. 4D is a simplified cross-sectional view of a portion of a package 400′ that includes the inductive device 400 based on the first example variation, according to aspects of the disclosure. FIG. 4D is a simplified cross-sectional view corresponding to the reference line B-B′ of FIG. 4C. The components that are the same or similar to those in FIGS. 3A and 3B are given the same reference numbers, and the detailed description thereof may be simplified or omitted.

As shown in FIG. 4D, a interconnect 430 may be disposed at the intermediate layer and configured to connect the pillar structure 332c and the pillar structure 332d. In this example, pillar structure 332c may correspond to conductive structure 232a in FIGS. 4B and 4C; pillar structure 332d may correspond to conductive structure 234a in FIGS. 4B and 4C; and interconnect 430 may correspond to interconnect 422 in FIGS. 4B and 4C. In some aspects, the interconnects 422, 424, 426, and 428 and the corresponding conductive structures connected thereto may correspond to a configuration similar to the example based on the interconnect 430, the pillar structure 332c, and the pillar structure 332d as shown in FIG. 4D.

In at least one example, compared to an inductive device based on the inductive device 200 with similar dimensions, an inductive device based on the inductive device 400 (e.g., the first example variation) may have at least 30% increase in the coupling coefficient and around 50% reduction in the DC resistance, and have about at least 70% of the self-inductance that may still provide sufficient inductance for applicants such as being used in conjunction with an output stage of a DC converter of an PMIC.

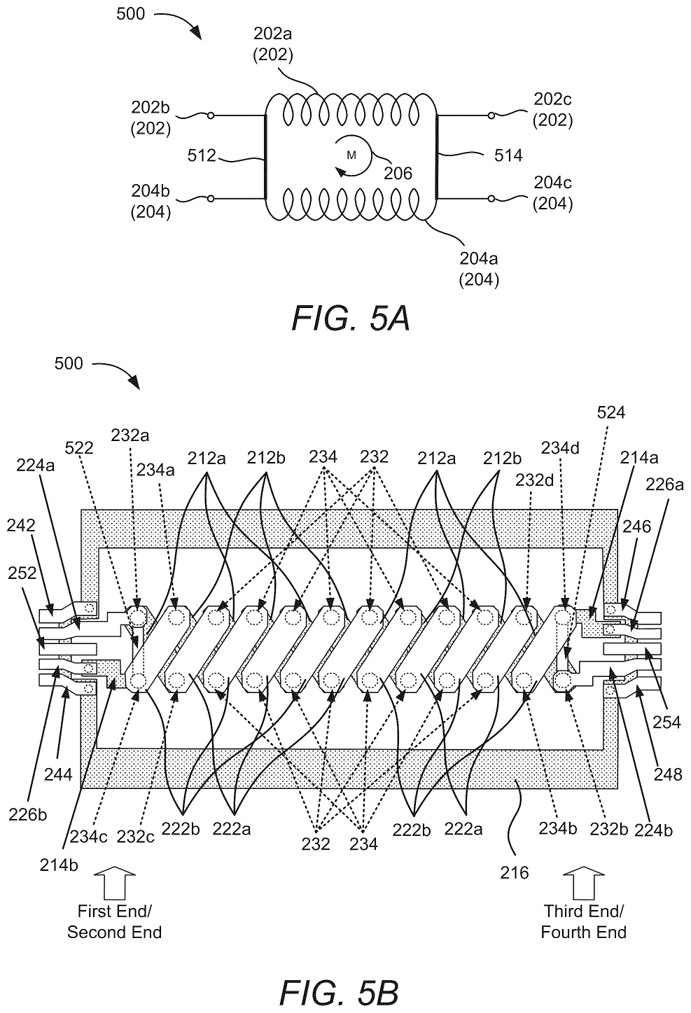

FIG. 5A is a circuit diagram of an inductive device 500 based on a second example variation of the inductive device 200, according to aspects of the disclosure. In some aspects, the components in FIG. 5A that are the same or similar to those in FIG. 2A are given the same reference numbers, and detailed description thereof may be simplified or omitted.

In some aspects, compared with the inductive device 200, the inductive device 500 may further include interconnects 512 and 514. In some aspects, the interconnect 512 may electrically connect a first end of the first coil structure 202a to a second end of the second coil structure 204a corresponding to the first end of the first coil structure 202a. In some aspects, the interconnect 514 may electrically connect a third end of the first coil structure 202a to a fourth end of the second coil structure 204a corresponding to the third end of the first coil structure 202a.

FIG. 5B is a simplified top view of a portion of the inductive device 500 based on the second example variation, according to aspects of the disclosure. In some aspects, components in FIG. 5B that are the same or similar to those in FIGS. 2B and 4C are given the same reference numbers, and detailed description thereof may be simplified or omitted.

As shown in FIG. 5B, the inductive device 500 may include a first interconnect 522 that is configured to connect a conductive structure 232a of the first set of conductive structures 232 disposed at a first end of the first coil structure to a conductive structure 234c of the second set of conductive structures 234 disposed at a second end of the second coil structure corresponding to the first end of the first coil structure. The inductive device 500 may include a second interconnect 524 that is configured to connect a conductive structure 232b of the first set of conductive structures 232 disposed at a third end of the first coil structure to a fourth conductive structure 234d of the second set of conductive structures 234 disposed at a fourth end of the second coil structure corresponding to the third end of the first coil structure.

In some aspects, the interconnects 522 and 524 and the corresponding conductive structures connected thereto may correspond to a configuration similar to the example based on the interconnect 430, the pillar structure 332c, and the pillar structure 332d as shown in FIG. 4D.

In at least one example, compared to an inductive device based on the inductive device 200 with similar dimensions, an inductive device based on the inductive device 500 (e.g., the second example variation) may have at least 30% increase in the coupling coefficient and around 50% reduction in the DC resistance, and have about at least 70% of the self-inductance that may still provide sufficient inductance for applicants such as being used in conjunction with an output stage of a DC converter of an PMIC.

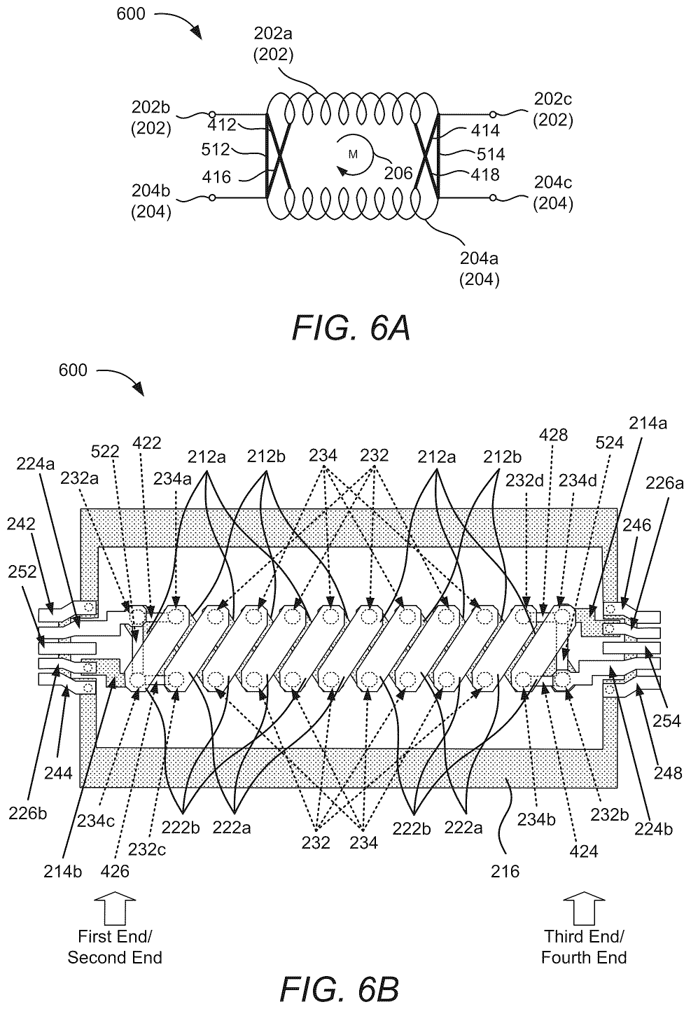

FIG. 6A is a circuit diagram of an inductive device 600 based on a third example variation of the inductive device 200, according to aspects of the disclosure. FIG. 6B is a simplified top view of a portion of the inductive device 600 based on the third example variation, according to aspects of the disclosure. In some aspects, the inductive device 600 based on the third example variation may be considered as a combination of the second variation and the third variation. Accordingly, the components in FIG. 6A that are the same or similar to those in FIGS. 4A and 5A are given the same reference numbers, and detailed description thereof may be simplified or omitted. Also, the components in FIG. 6B that are the same or similar to those in FIGS. 4C and 5B are given the same reference numbers, and detailed description thereof may be simplified or omitted.

As shown in FIG. 6A, compared with the inductive device 400, the inductive device 600 may further include interconnects 512 and 514 as illustrated in FIG. 5A. As shown in FIG. 5B, compared with the inductive device 400, the inductive device 600 may further include a interconnect 522 that is configured to connect the conductive structure 232a of the first set of conductive structures 232 to the conductive structure 234c of the second set of conductive structures 234; and a interconnect 524 that is configured to connect the conductive structure 232b of the first set of conductive structures 232 to the conductive structure 234d of the second set of conductive structures 234.

In at least one example, compared to an inductive device based on the inductive device 200 with similar dimensions, an inductive device based on the inductive device 600 (e.g., the third example variation) may have at least 30% increase in the coupling coefficient and around 50% reduction in the DC resistance, and have about at least 70% of the self-inductance that may still provide sufficient inductance for applicants such as being used in conjunction with an output stage of a DC converter of an PMIC.

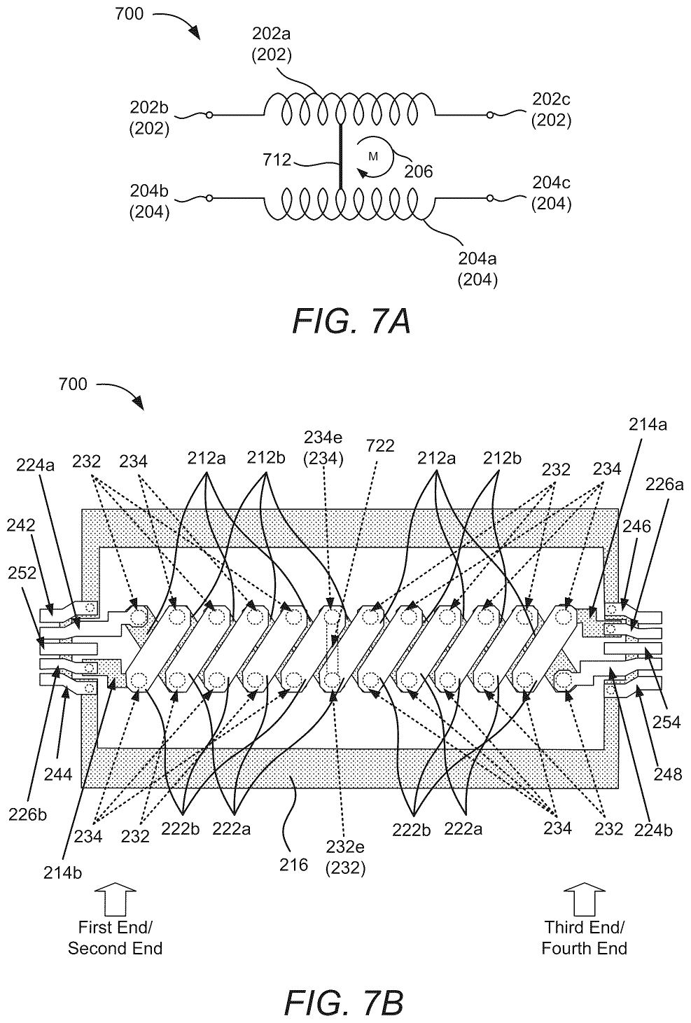

FIG. 7A is a circuit diagram of an inductive device 700 based on a fourth example variation of the inductive device 200, according to aspects of the disclosure. In some aspects, the components in FIG. 7A that are the same or similar to those in FIG. 2A are given the same reference numbers, and detailed description thereof may be simplified or omitted. In some aspects, compared with the inductive device 200, the inductive device 700 may further include a interconnect 712. In some aspects, the interconnect 712 may electrically connect a middle portion (e.g., further away from any end for more than a half-turn) of the first coil structure 202a to a middle portion of the second coil structure 204a (e.g., further away from any end for more than a half-turn).

FIG. 7B is a simplified top view of a portion of the inductive device 700 based on the fourth example variation, according to aspects of the disclosure. In some aspects, components in FIG. 7B that are the same or similar to those in FIG. 2B are given the same reference numbers, and detailed description thereof may be simplified or omitted.

As shown in FIG. 7B, the inductive device 700 may include a interconnect 722 that is configured to connect a conductive structure 232e of the first set of conductive structures 232 disposed at a middle portion of the first coil structure to a conductive structure 234c of the second set of conductive structures 234 disposed at a middle portion of the second coil structure. In some aspects, the interconnect 722 and the corresponding conductive structures connected thereto may correspond to a configuration similar to the example based on the interconnect 430, the pillar structure 332c, and the pillar structure 332d as shown in FIG. 4D.

In at least one example, compared to an inductive device based on the inductive device 200 with similar dimensions, an inductive device based on the inductive device 700 (e.g., the fourth example variation) may have at least 15% increase in the coupling coefficient, and have about at least 80% of the self-inductance that may still provide sufficient inductance for applicants such as being used in conjunction with an output stage of a DC converter of an PMIC. In some aspects, compared to an inductive device based on the inductive device 200, an inductive device based on the inductive device 700 (e.g., the fourth example variation) may not have reduction in the DC resistance.

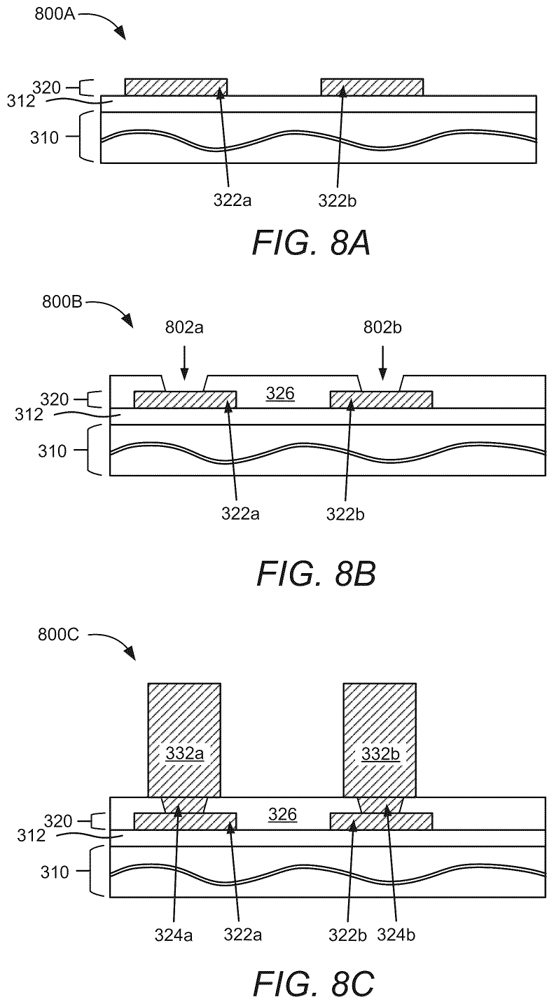

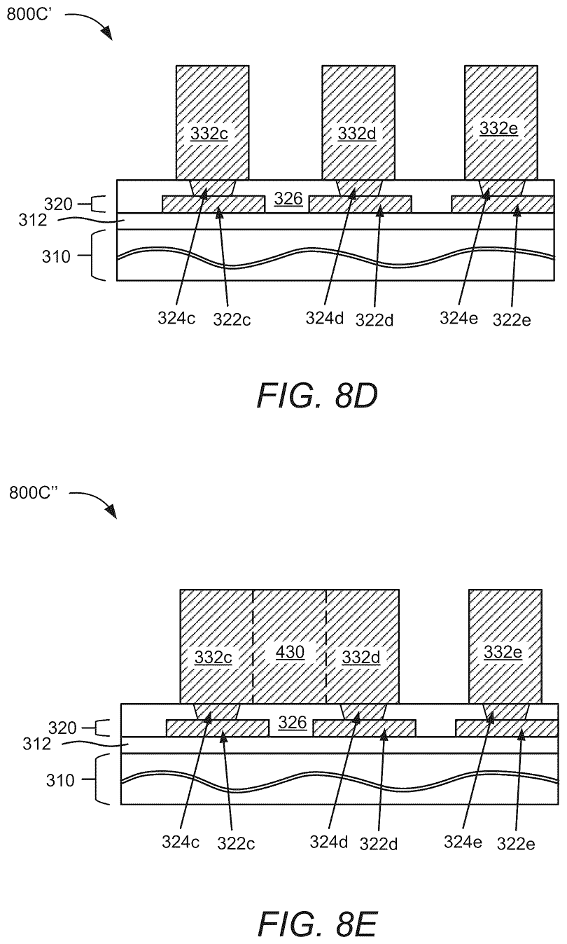

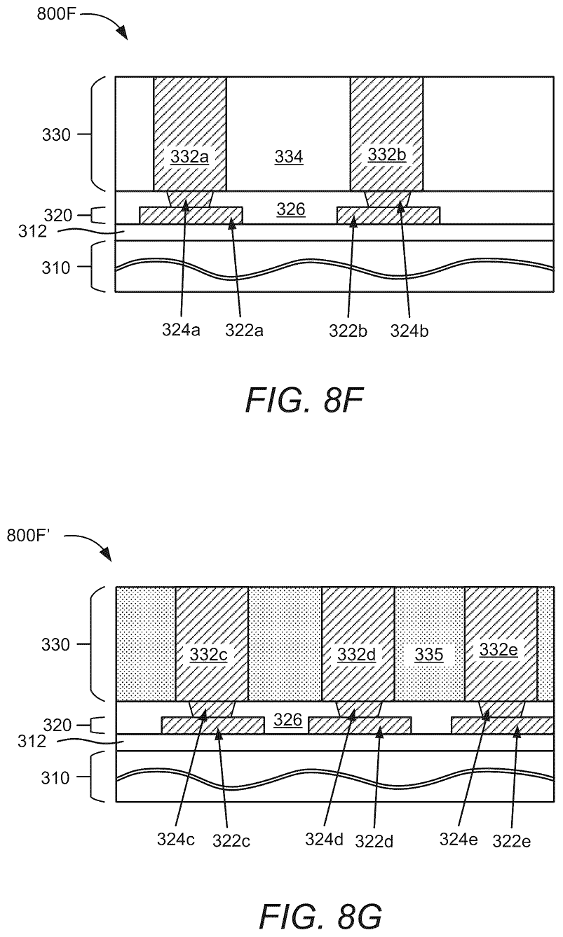

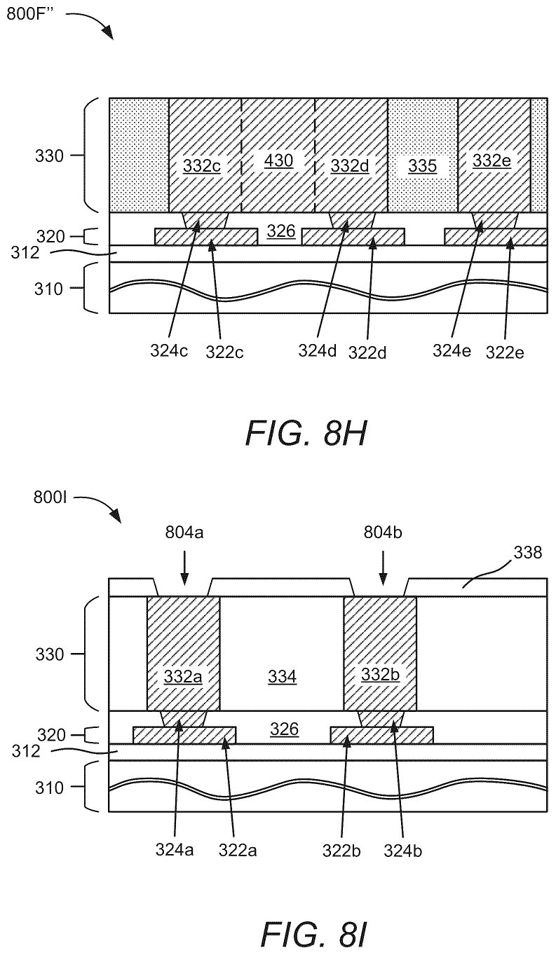

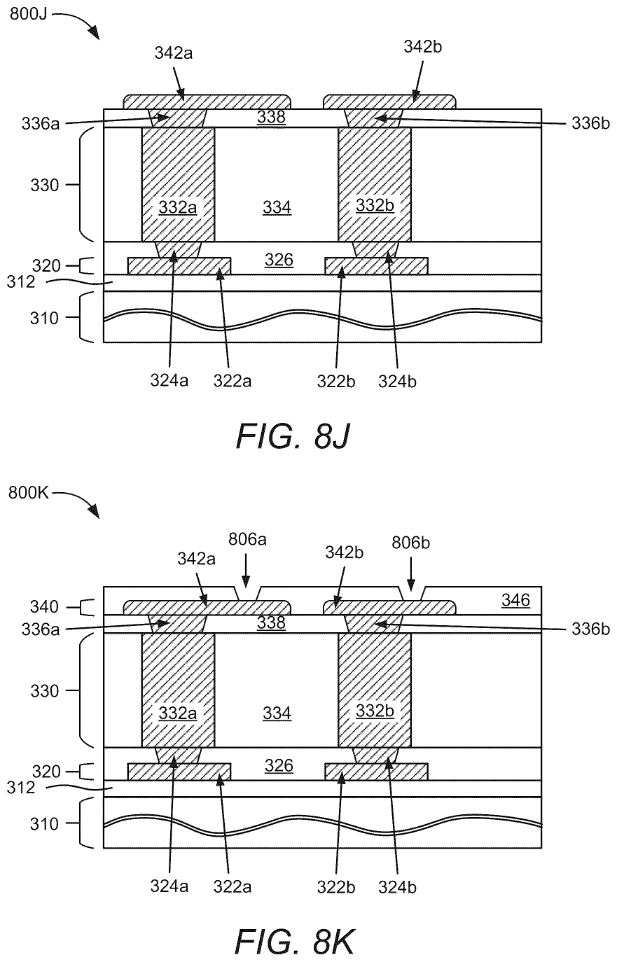

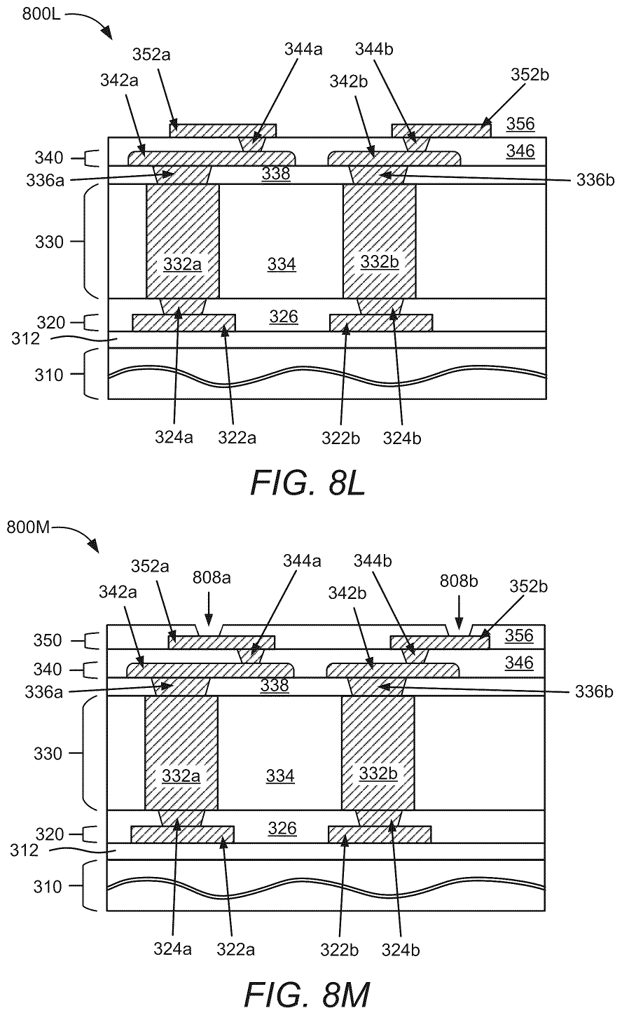

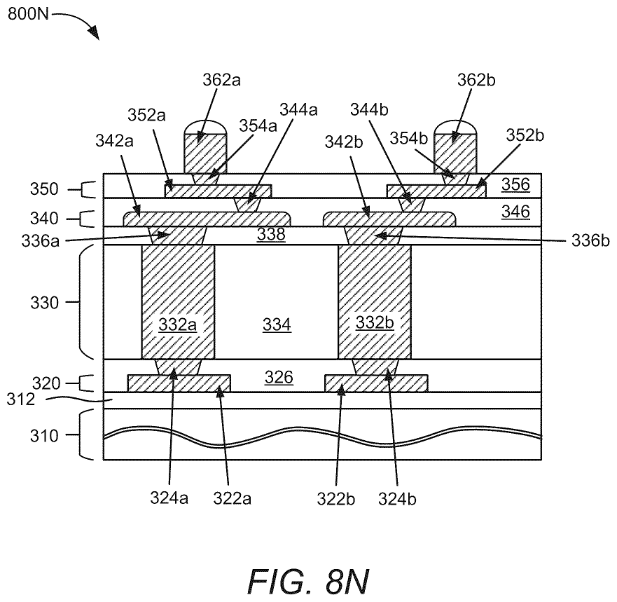

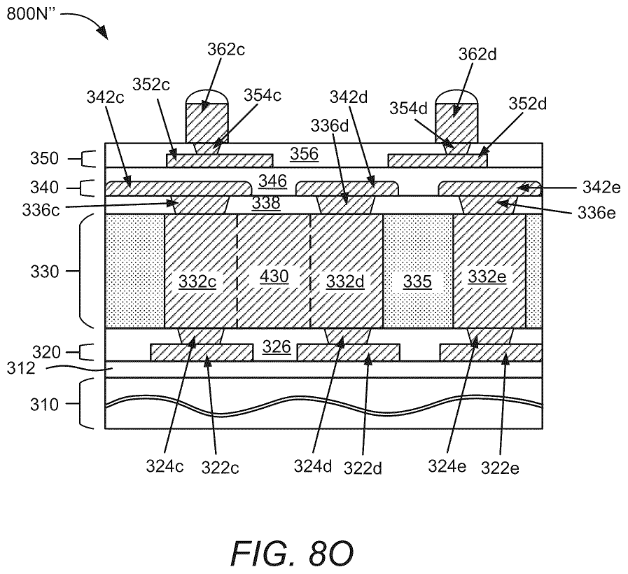

FIGS. 8A-8O illustrate structures at various stages of manufacturing an inductive device based on various variations illustrated in FIGS. 4A-7B, according to aspects of the disclosure. The components illustrated in FIGS. 8A-8O that are the same or similar to those of FIGS. 3A, 3B, and 4D are given the same reference numbers, and the detailed description thereof may be simplified or omitted.

FIG. 8A shows a cross-sectional view of a structure 800A, which corresponds to a portion of a package that includes an inductive device configured based on one or more of the example variations illustrated in FIGS. 4A-7B. At this stage, a first dielectric layer 312 may be formed over a substrate portion 310. In some aspects, the substrate portion 310 may correspond to a semiconductor substrate or carrier. In some aspects, the substrate portion 310 may include a semiconductor substrate, components of PMIC circuitry formed on the substrate, and one or more metallization layers formed on the components and the semiconductor substrate. In some aspects, the first dielectric layer 312 may be formed based on a deposition process, a spin-coating process, a build-up film application process, or any combination thereof. In some aspects, the first dielectric layer 312 may include silicon oxide or polyimide.

At this stage, one or more conductive patterns (e.g., conductive patterns 322a and 322b in FIG. 8A and conductive patterns 322c, 322d, and 322e in FIGS. 8D and 8E) may be formed at a first metallization layer 320 over the first dielectric layer 312. In some aspects, the one or more conductive patterns at the first metallization layer 320 may be formed based on forming photo resist patterns over the first dielectric layer 312, performing a conductive material deposition or plating through at least the openings defined by the photo resist patterns, and then removing the photo resist patterns and excessive conductive material. In some aspects, the conductive material may include copper, aluminum, gold, or a combination thereof.

FIG. 8B shows a cross-sectional view of a structure 800B that is formed based on the structure 800A by forming a second dielectric layer 326 over the first dielectric layer 312 and the one or more conductive patterns at the first metallization layer 320, and forming openings over at least a subset of the one or more conductive patterns at the first metallization layer 320 (e.g., an opening 802a over the conductive pattern 322a and an opening 802b over the conductive pattern 322b). In some aspects, the second dielectric layer 326 may be formed based on a deposition process, a spin-coating process, a build-up film application process, or any combination thereof. In some aspects, the second dielectric layer 326 may include silicon oxide or polyimide. In some aspects, the openings 802a and 802b may be formed based on an etching process, a mechanical drilling process, or a laser drilling process.

FIG. 8C shows a cross-sectional view of a structure 800C that is formed based on the structure 800B by forming one or more via structures (e.g., via structures 324a and 324b in FIG. 8C and via structures 324c, 324d, and 324c in FIGS. 8D and 8E) in the corresponding openings and forming one or more pillar structures (e.g., pillar structures 332a and 332b in FIG. 8C and pillar structures 332c, 332d, and 332e in FIGS. 8D and 8E) over the corresponding via structures. In some aspects, the one or more via structures may be formed based on performing a conductive material deposition or plating through at least the openings (e.g., the openings 802a and 802b), and then removing excessive conductive material over the second dielectric layer 326. In some aspects, the conductive material may include copper, aluminum, gold, or a combination thereof.

In some aspects, the one or more pillar structures (e.g., pillar structures 332a and 332b in FIG. 8C and pillar structures 332c, 332d, and 332e in FIGS. 8D and 8E) may be formed based on forming photo resist patterns over the second dielectric layer 322, performing a conductive material deposition or plating through at least the openings defined by the photo resist patterns, and then removing the photo resist patterns and excessive conductive material. In some aspects, the conductive material may include copper, aluminum, gold, or a combination thereof.

In some aspects, the structure 800C in FIG. 8C corresponds to forming a portion of the package that does not include the inductive device. In some aspects, other portions of the package as further illustrated in FIGS. 8D and 8E may be formed at the same stage illustrated in FIG. 8C.

In some aspects, FIG. 8D shows a cross-sectional view of a structure 800C′ that corresponds to forming a portion of the package that includes the inductive device having no interconnect between the pillar structures 332c, 332d, and 332e. In some aspects, FIG. 8E shows a cross-sectional view of a structure 800C″ that corresponds to forming a portion of the IC package that includes the inductive device having a interconnect 430 between the pillar structures 332c and 332d. In some aspects, the interconnect 430 may be formed together with the pillar structures 332c and 332d at the stage illustrated in FIG. 8C. In some aspects, a package that includes an inductive device as illustrated in FIGS. 4A-7B, may include various portions correspond to the examples illustrated in FIGS. 8C-8E.

FIG. 8F shows a cross-sectional view of a structure 800F that is formed based on the structure 800C by forming a third dielectric layer 334 at an intermediate layer 330. In some aspects, the structure 800F in FIG. 8F corresponds to forming a portion of the package that does not include the inductive device. In some aspects, other portions of the package as further illustrated in FIGS. 8G and 8H may be formed at the same stage illustrated in FIG. 8F. FIG. 8G shows a cross-sectional view of a structure 800F′ that is formed based on the structure 800C′ by disposing a magnetic material 335 at the intermediate layer 330. FIG. 8H shows a cross-sectional view of a structure 800F″ that is formed based on the structure 800C″ by disposing the magnetic material 335 at the intermediate layer 330.

In some aspects, the third dielectric layer 334 may be formed based on a deposition process, a spin-coating process, a build-up film application process, or any combination thereof. In some aspects, the third dielectric layer 334 may include silicon oxide or polyimide. In some aspects, the magnetic material 335 may be formed based on a deposition process, a spin-coating process, a build-up film application process, or any combination thereof. In some aspects, the magnetic material 335 may include carbon, silicon, chromium, iron, platinum, phosphorus, or any combination thereof.

In some aspects, the third dielectric layer 334 and the magnetic material 335 may be separately formed based on forming photo resist patterns over the second dielectric layer 326, forming the third dielectric layer 326 through at least the openings defined by the photo resist patterns, removing the photo resist patterns and excessive dielectric material, and disposing the magnetic material 335 through at least the openings defined based on the removal of the photo resist patterns.

FIG. 8I shows a cross-sectional view of a structure 8001 that is formed based on the structure 800F by forming a fourth dielectric layer 338 over the intermediate layer 330, and forming openings over at least a subset the pillar structures at the intermediate layer 330 (e.g., an opening 804a over the pillar structure 332a and an opening 804b over the pillar structure 332b). In some aspects, the fourth dielectric layer 338 may be formed based on a deposition process, a spin-coating process, a build-up film application process, or any combination thereof. In some aspects, the fourth dielectric layer 338 may include silicon oxide or polyimide. In some aspects, the openings 804a and 804b may be formed based on an etching process, a mechanical drilling process, or a laser drilling process.

FIG. 8J shows a cross-sectional view of a structure 800J that is formed based on the structure 8001 by forming one or more via structures (e.g., via structures 336a and 336b in FIG. 8J and via structures 336c, 336d, and 336e in FIG. 8O) in the corresponding openings and forming one or more conductive patterns (e.g., conductive patterns 342a and 342b in FIG. 8C and conductive patterns 342c, 342d, and 342e in FIG. 8O) over the corresponding via structures. In some aspects, the one or more via structures may be formed based on performing a conductive material deposition or plating through at least the openings (e.g., the openings 804a and 804b), and then removing excessive conductive material over the fourth dielectric layer 338. In some aspects, the conductive material may include copper, aluminum, gold, or a combination thereof.

In some aspects, the one or more conductive patterns (e.g., conductive patterns 342a and 342b in FIG. 8C and conductive patterns 342c, 342d, and 342e in FIG. 8O) may be formed based on forming photo resist patterns over the fourth dielectric layer 338, performing a conductive material deposition or plating through at least the openings defined by the photo resist patterns, and then removing the photo resist patterns and excessive conductive material. In some aspects, the conductive material may include copper, aluminum, gold, or a combination thereof.

FIG. 8K shows a cross-sectional view of a structure 800K that is formed based on the structure 800J by forming a fifth dielectric layer 346 over the fourth dielectric layer 338, and forming openings over at least a subset of the one or more conductive patterns (e.g., an opening 806a over the conductive pattern 342a and an opening 806b over the conductive pattern 342b). In some aspects, the fifth dielectric layer 346 may be formed based on a deposition process, a spin-coating process, a build-up film application process, or any combination thereof. In some aspects, the fifth dielectric layer 346 may include silicon oxide or polyimide. In some aspects, the openings 806a and 806b may be formed based on an etching process, a mechanical drilling process, or a laser drilling process.

FIG. 8L shows a cross-sectional view of a structure 800L that is formed based on the structure 800K by forming one or more via structures (e.g., via structures 344a and 344b in FIG. 8L) in the corresponding openings and forming one or more conductive patterns (e.g., conductive patterns 352a and 352b in FIG. 8L) over the corresponding via structures or over the fifth dielectric layer 346 (e.g., conductive patterns 352c and 352d in FIG. 8O). In some aspects, the one or more via structures may be formed based on performing a conductive material deposition or plating through at least the openings (e.g., the openings 806a and 806b), and then removing excessive conductive material over the fifth dielectric layer 346. In some aspects, the conductive material may include copper, aluminum, gold, or a combination thereof.

In some aspects, the one or more conductive patterns (e.g., conductive patterns 352a and 352b in FIG. 8L and conductive patterns 352c and 352d in FIG. 8O) may be formed based on forming photo resist patterns over the fifth dielectric layer 346, performing a conductive material deposition or plating through at least the openings defined by the photo resist patterns, and then removing the photo resist patterns and excessive conductive material. In some aspects, the conductive material may include copper, aluminum, gold, or a combination thereof.

FIG. 8M shows a cross-sectional view of a structure 800M that is formed based on the structure 800L by forming a sixth dielectric layer 356 over the fifth dielectric layer 346, and forming openings over at least a subset of the one or more conductive patterns (e.g., an opening 808a over the conductive pattern 352a and an opening 808b over the conductive pattern 352b). In some aspects, the sixth dielectric layer 356 may be formed based on a deposition process, a spin-coating process, a build-up film application process, or any combination thereof. In some aspects, the sixth dielectric layer 356 may include silicon oxide or polyimide. In some aspects, the openings 808a and 808b may be formed based on an etching process, a mechanical drilling process, or a laser drilling process.

FIG. 8N shows a cross-sectional view of a structure 800N that is formed based on the structure 800K by forming one or more via structures (e.g., via structures 354a and 354b in FIG. 8N) in the corresponding openings and forming one or more terminal structures (e.g., terminal structures 362a and 362b in FIG. 8N) over the corresponding via structures. In some aspects, the structure 800N in FIG. 8N corresponds to forming a portion of the IC package that does not include the inductive device. In some aspects, other portions of the IC package as further illustrated in FIG. 8H may be formed at the stage illustrated in FIG. 8O. For example, FIG. 8O shows a cross-sectional view of a structure 800N″ that is formed based on the structure 800F″ followed by the stages as illustrated in FIGS. 8I-8N.

In some aspects, the one or more via structures may be formed based on performing a conductive material deposition or plating through at least the openings, and then removing excessive conductive material over the sixth dielectric layer 356. In some aspects, the conductive material may include copper, aluminum, gold, or a combination thereof. In some aspects, the one or more terminal structures may be formed based on forming photo resist patterns over the sixth dielectric layer 356, forming corresponding copper pillars, and forming corresponding solder portions over the copper pillars.

In some aspects, the structure illustrated in FIGS. 8N and 8O may correspond to the structure for forming a package with an inductive device based on various variations illustrated in FIGS. 4A-7B.

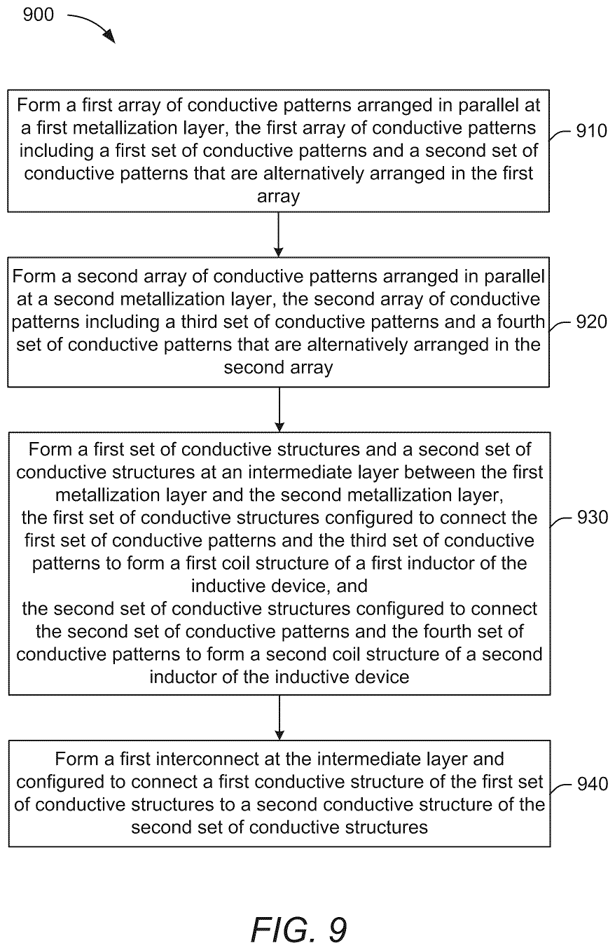

FIG. 9 illustrates a method 900 of manufacturing an inductive device (such as the inductive device based on various variations illustrated in FIGS. 4A-7B), according to aspects of the disclosure. In some aspects, FIGS. 8A-8O may show the structures at various stages of the method 900.

At operation 910, a first array of conductive patterns arranged in parallel (e.g., the conductive patterns 212a and 212b in FIGS. 4C, 5B, 6B, and 7B) may be formed at a first metallization layer (e.g., the first metallization layer 320 in FIG. 4D). In some aspects, the first array of conductive patterns may include a first set of conductive patterns (e.g., the first set of conductive patterns 212a in FIGS. 4C, 5B, 6B, and 7B) and a second set of conductive patterns (e.g., the second set of conductive patterns 212b in FIGS. 4C, 5B, 6B, and 7B) that are alternatively arranged in the first array. In some aspects, operation 910 may correspond to the stage as illustrated in FIG. 8A.

At operation 920, a second array of conductive patterns arranged in parallel (e.g., the conductive patterns 222a and 222b in FIGS. 4C, 5B, 6B, and 7B) may be formed at a second metallization layer (e.g., the second metallization layer 340 in FIG. 4D). In some aspects, the second array of conductive patterns may include a third set of conductive patterns (e.g., the third set of conductive patterns 222a in FIGS. 4C, 5B, 6B, and 7B) and a fourth set of conductive patterns (e.g., the fourth set of conductive patterns 222b in FIGS. 4C, 5B, 6B, and 7B) that are alternatively arranged in the second array. In some aspects, operation 920 may correspond to the stage as illustrated in FIG. 8J.

At operation 930, a first set of conductive structures (e.g., the first set of conductive structures 232 in FIGS. 4C, 5B, 6B, and 7B) and a second set of conductive structures (e.g., the second set of conductive structures 234 in FIGS. 4C, 5B, 6B, and 7B) may be formed at an intermediate layer (e.g., e.g., the intermediate layer 330 in FIG. 4D) between the first metallization layer and the second metallization layer. In some aspects, the first set of conductive structures may connect the first set of conductive patterns and the third set of conductive patterns to form a first coil structure of a first inductor of the inductive device. In some aspects, the second set of conductive structures may connect the second set of conductive patterns and the fourth set of conductive patterns to form a second coil structure of a second inductor of the inductive device. In some aspects, operation 930 may correspond to the stages as illustrated in FIGS. 8B-8I.

At operation 940, a first interconnect (e.g., the interconnects 412, 414, 416, and 418 in FIGS. 4 and 6; the interconnects 512 and 514 in FIGS. 5 and 6; the interconnect 712 in FIG. 7; and the interconnect 430 in FIG. 4D) may be formed at the intermediate layer and configured to connect a first conductive structure of the first set of conductive structures to a second conductive structure of the second set of conductive structures. In some aspects, operation 940 may correspond to the stages as illustrated in FIG. 8E.

In some aspects, the first array of conductive patterns and the second array of conductive patterns may include a material that includes copper, aluminum, gold, or a combination thereof. In some aspects, the first set of conductive structures and the second set of conductive structures may include a material that includes copper, aluminum, gold, or a combination thereof.

In some aspects, the method 900 may further include forming a magnetic material (e.g., the magnetic material 335 in FIGS. 8G and 8H) disposed at the intermediate layer and between the first array of conductive patterns and the second array of conductive patterns. In some aspects, the magnetic material may include carbon, silicon, chromium, iron, platinum, phosphorus, or any combination thereof.

In some aspects, as illustrated in FIGS. 4A-4D, the first interconnect (e.g., corresponding to the interconnect 422) may connect the first conductive structure of the first set of conductive structures disposed at a first end of the first coil structure to the second conductive structure of the second set of conductive structures disposed at a half-turn position of the second coil structure from a second end of the second coil structure corresponding to the first end of the first coil structure. In some aspects, the method 900 may further include forming a second interconnect (e.g., corresponding to the interconnect 424) at the intermediate layer, where the second interconnect may connect a third conductive structure of the first set of conductive structures disposed at a third end of the first coil structure to a fourth conductive structure of the second set of conductive structures disposed at a half-turn position of the second coil structure from a fourth end of the second coil structure corresponding to the third end of the first coil structure.

Moreover, the method 900 may include forming a third interconnect (e.g., corresponding to the interconnect 426) at the intermediate layer, where the third interconnect may connect a fifth conductive structure of the first set of conductive structures disposed at a half-turn position of the first coil structure from the first end of the first coil structure to a sixth conductive structure of the second set of conductive structures disposed at the second end of the second coil structure. Also, the method 900 may include forming a fourth interconnect (e.g., corresponding to the interconnect 428) at the intermediate layer, where the fourth interconnect may connect a seventh conductive structure of the first set of conductive structures disposed at a half-turn position of the first coil structure from the third end of the first coil structure to an eighth conductive structure of the second set of conductive structures disposed at the fourth end of the second coil structure.

In some aspects, as illustrated in FIGS. 6A-6B, the method 900 may further include forming a fifth interconnect (e.g., corresponding to the interconnect 522) at the intermediate layer, where the fifth interconnect may connect the first conductive structure of the first set of conductive structures disposed at the first end of the first coil structure to the sixth conductive structure of the second set of conductive structures disposed at the second end of the second coil structure. Also, the method 900 may include forming a sixth interconnect (e.g., corresponding to the interconnect 524) at the intermediate layer, where the sixth interconnect may connect the third conductive structure of the first set of conductive structures disposed at the third end of the first coil structure to the eighth conductive structure of the second set of conductive structures disposed at the fourth end of the second coil structure.

In some aspects, as illustrated in FIGS. 5A-5B, the first interconnect (e.g., corresponding to the interconnect 522) may connect the first conductive structure of the first set of conductive structures disposed at a first end of the first coil structure to the second conductive structure of the second set of conductive structures disposed at a second end of the second coil structure corresponding to the first end of the first coil structure. In some aspects, the method 900 may further include forming a second interconnect (e.g., corresponding to the interconnect 524) at the intermediate layer, where the second interconnect may connect a third conductive structure of the first set of conductive structures disposed at a third end of the first coil structure to a fourth conductive structure of the second set of conductive structures disposed at a fourth end of the second coil structure corresponding to the third end of the first coil structure.

In some aspects, as illustrated in FIGS. 7A-7B, the first interconnect (e.g., corresponding to the interconnect 722) may connect the first conductive structure of the first set of conductive structures disposed at a middle portion of the first coil structure to the second conductive structure of the second set of conductive structures disposed at a middle portion of the second coil structure.

As will be appreciated, a technical advantage of the method 900 is to manufacture an inductive device that includes magnetic coupled inductors. By introducing at least one interconnect at an intermediate layer and configured to connect one of the first set of conductive structures to one of the second set of conductive structures, the resulting inductive device may provide a suitable inductance while further increase the magnetic coupling coefficient and/or reduce the DC resistance, without incurring additional manufacturing complexity and/or costs.

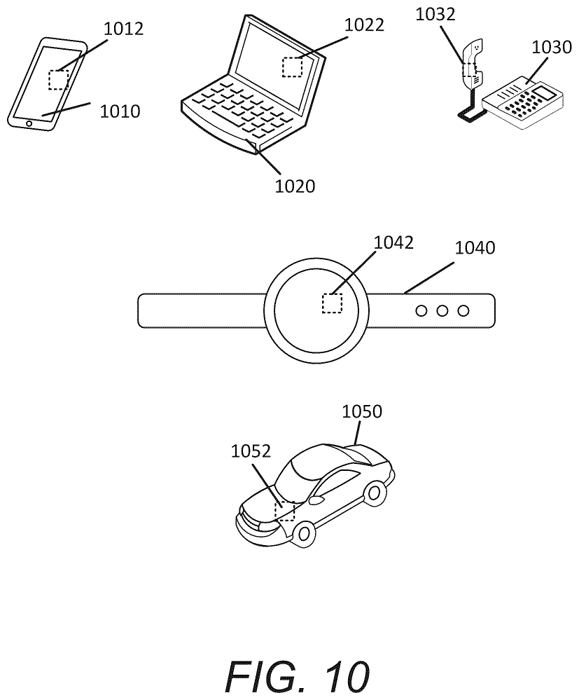

FIG. 10 illustrates various electronic devices that may include an inductive device described herein (such as an inductive device based on various variations illustrated in FIGS. 4A-7B), according to aspects of the disclosure. For example, a mobile phone device 1010, a laptop computer device 1020, a fixed location terminal device 1030, a wearable device 1040, or an electronic device onboard an automotive vehicle 1050 may respectively include one or more inductive devices 1012, 1022, 1032, 1042, and 1052 (e.g., corresponding to inductive devices to be used in association with respective PMICs). The devices 1010, 1020, 1030, and 1040 and the vehicle 1050 illustrated in FIG. 10 are merely exemplary. Other apparatuses or devices that may feature one or more inductive devices as described herein may include, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An inductive device, comprising: a first array of conductive patterns arranged in parallel at a first metallization layer, the first array of conductive patterns including a first set of conductive patterns and a second set of conductive patterns that are alternatively arranged in the first array; a second array of conductive patterns arranged in parallel at a second metallization layer, the second array of conductive patterns including a third set of conductive patterns and a fourth set of conductive patterns that are alternatively arranged in the second array; a first set of conductive structures and a second set of conductive structures at an intermediate layer between the first metallization layer and the second metallization layer, the first set of conductive structures configured to connect the first set of conductive patterns and the third set of conductive patterns to form a first coil structure of a first inductor of the inductive device, and the second set of conductive structures configured to connect the second set of conductive patterns and the fourth set of conductive patterns to form a second coil structure of a second inductor of the inductive device; and a first interconnect at the intermediate layer and configured to connect a first conductive structure of the first set of conductive structures to a second conductive structure of the second set of conductive structures.

Clause 2. The inductive device of clause 1, wherein: the first array of conductive patterns and the second array of conductive patterns comprise a conductive material that includes copper, aluminum, gold, or a combination thereof, and the first set of conductive structures and the second set of conductive structures comprise a conductive material that includes copper, aluminum, gold, or a combination thereof.

Clause 3. The inductive device of any of clauses 1 to 2, further comprising: a magnetic material disposed at the intermediate layer and between the first array of conductive patterns and the second array of conductive patterns.

Clause 4. The inductive device of clause 3, wherein: the magnetic material comprises carbon, silicon, chromium, iron, platinum, phosphorus, or any combination thereof.

Clause 5. The inductive device of clause 1, wherein: the first interconnect is configured to connect the first conductive structure of the first set of conductive structures disposed at a first end of the first coil structure to the second conductive structure of the second set of conductive structures disposed at a half-turn position of the second coil structure from a second end of the second coil structure corresponding to the first end of the first coil structure, and the inductive device further comprises a second interconnect at the intermediate layer and configured to connect a third conductive structure of the first set of conductive structures disposed at a third end of the first coil structure to a fourth conductive structure of the second set of conductive structures disposed at a half-turn position of the second coil structure from a fourth end of the second coil structure corresponding to the third end of the first coil structure.

Clause 6. The inductive device of clause 5, further comprising: a third interconnect at the intermediate layer and configured to connect a fifth conductive structure of the first set of conductive structures disposed at a half-turn position of the first coil structure from the first end of the first coil structure to a sixth conductive structure of the second set of conductive structures disposed at the second end of the second coil structure, and a fourth interconnect at the intermediate layer and configured to connect a seventh conductive structure of the first set of conductive structures disposed at a half-turn position of the first coil structure from the third end of the first coil structure to an eighth conductive structure of the second set of conductive structures disposed at the fourth end of the second coil structure.

Clause 7. The inductive device of clause 6, further comprising: a fifth interconnect at the intermediate layer and configured to connect the first conductive structure of the first set of conductive structures disposed at the first end of the first coil structure to the sixth conductive structure of the second set of conductive structures disposed at the second end of the second coil structure, and a sixth interconnect at the intermediate layer and configured to connect the third conductive structure of the first set of conductive structures disposed at the third end of the first coil structure to the eighth conductive structure of the second set of conductive structures disposed at the fourth end of the second coil structure.

Clause 8. The inductive device of clause 1, wherein: the first interconnect is configured to connect the first conductive structure of the first set of conductive structures disposed at a first end of the first coil structure to the second conductive structure of the second set of conductive structures disposed at a second end of the second coil structure corresponding to the first end of the first coil structure, and the inductive device further comprises a second interconnect at the intermediate layer and configured to connect a third conductive structure of the first set of conductive structures disposed at a third end of the first coil structure to a fourth conductive structure of the second set of conductive structures disposed at a fourth end of the second coil structure corresponding to the third end of the first coil structure.

Clause 9. The inductive device of clause 1, wherein: the first interconnect is configured to connect the first conductive structure of the first set of conductive structures disposed at a middle portion of the first coil structure to the second conductive structure of the second set of conductive structures disposed at a middle portion of the second coil structure.

Clause 10. A method of manufacturing an inductive device, comprising: forming a first array of conductive patterns arranged in parallel at a first metallization layer, the first array of conductive patterns including a first set of conductive patterns and a second set of conductive patterns that are alternatively arranged in the first array; forming a second array of conductive patterns arranged in parallel at a second metallization layer, the second array of conductive patterns including a third set of conductive patterns and a fourth set of conductive patterns that are alternatively arranged in the second array; forming a first set of conductive structures and a second set of conductive structures at an intermediate layer between the first metallization layer and the second metallization layer, the first set of conductive structures configured to connect the first set of conductive patterns and the third set of conductive patterns to form a first coil structure of a first inductor of the inductive device, and the second set of conductive structures configured to connect the second set of conductive patterns and the fourth set of conductive patterns to form a second coil structure of a second inductor of the inductive device; and forming a first interconnect at the intermediate layer and configured to connect a first conductive structure of the first set of conductive structures to a second conductive structure of the second set of conductive structures.

Clause 11. The method of clause 10, wherein: the first array of conductive patterns and the second array of conductive patterns comprise a material that includes copper, aluminum, gold, or a combination thereof, and the first set of conductive structures and the second set of conductive structures comprise a material that includes copper, aluminum, gold, or a combination thereof.

Clause 12. The method of any of clauses 10 to 11, further comprising: forming a magnetic material disposed at the intermediate layer and between the first array of conductive patterns and the second array of conductive patterns.

Clause 13. The method of clause 12, wherein: the magnetic material comprises carbon, silicon, chromium, iron, platinum, phosphorus, or any combination thereof.

Clause 14. The method of clause 10, wherein: the first interconnect is configured to connect the first conductive structure of the first set of conductive structures disposed at a first end of the first coil structure to the second conductive structure of the second set of conductive structures disposed at a half-turn position of the second coil structure from a second end of the second coil structure corresponding to the first end of the first coil structure, and the method further comprises forming a second interconnect at the intermediate layer, the second interconnect configured to connect a third conductive structure of the first set of conductive structures disposed at a third end of the first coil structure to a fourth conductive structure of the second set of conductive structures disposed at a half-turn position of the second coil structure from a fourth end of the second coil structure corresponding to the third end of the first coil structure.

Clause 15. The method of clause 14, further comprising: forming a third interconnect at the intermediate layer, the third interconnect configured to connect a fifth conductive structure of the first set of conductive structures disposed at a half-turn position of the first coil structure from the first end of the first coil structure to a sixth conductive structure of the second set of conductive structures disposed at the second end of the second coil structure, and forming a fourth interconnect at the intermediate layer, the fourth interconnect configured to connect a seventh conductive structure of the first set of conductive structures disposed at a half-turn position of the first coil structure from the third end of the first coil structure to an eighth conductive structure of the second set of conductive structures disposed at the fourth end of the second coil structure.

Clause 16. The method of clause 15, further comprising: forming a fifth interconnect at the intermediate layer, the fifth interconnect configured to connect the first conductive structure of the first set of conductive structures disposed at the first end of the first coil structure to the sixth conductive structure of the second set of conductive structures disposed at the second end of the second coil structure, and forming a sixth interconnect at the intermediate layer, the sixth interconnect configured to connect the third conductive structure of the first set of conductive structures disposed at the third end of the first coil structure to the eighth conductive structure of the second set of conductive structures disposed at the fourth end of the second coil structure.

Clause 17. The method of clause 10, wherein: the first interconnect is configured to connect the first conductive structure of the first set of conductive structures disposed at a first end of the first coil structure to the second conductive structure of the second set of conductive structures disposed at a second end of the second coil structure corresponding to the first end of the first coil structure, and the method further comprises forming a second interconnect at the intermediate layer, the second interconnect configured to connect a third conductive structure of the first set of conductive structures disposed at a third end of the first coil structure to a fourth conductive structure of the second set of conductive structures disposed at a fourth end of the second coil structure corresponding to the third end of the first coil structure.

Clause 18. The method of clause 10, wherein: the first interconnect is configured to connect the first conductive structure of the first set of conductive structures disposed at a middle portion of the first coil structure to the second conductive structure of the second set of conductive structures disposed at a middle portion of the second coil structure.

Clause 19. An electronic device, comprising: an inductive device that comprises: a first array of conductive patterns arranged in parallel at a first metallization layer, the first array of conductive patterns including a first set of conductive patterns and a second set of conductive patterns that are alternatively arranged in the first array; a second array of conductive patterns arranged in parallel at a second metallization layer, the second array of conductive patterns including a third set of conductive patterns and a fourth set of conductive patterns that are alternatively arranged in the second array; a first set of conductive structures and a second set of conductive structures at an intermediate layer between the first metallization layer and the second metallization layer, the first set of conductive structures configured to connect the first set of conductive patterns and the third set of conductive patterns to form a first coil structure of a first inductor of the inductive device, and the second set of conductive structures configured to connect the second set of conductive patterns and the fourth set of conductive patterns to form a second coil structure of a second inductor of the inductive device; and a first interconnect at the intermediate layer and configured to connect a first conductive structure of the first set of conductive structures to a second conductive structure of the second set of conductive structures.

Clause 20. The electronic device of clause 19, wherein: the first array of conductive patterns and the second array of conductive patterns comprise a material that includes copper, aluminum, gold, or a combination thereof, and the first set of conductive structures and the second set of conductive structures comprise a material that includes copper, aluminum, gold, or a combination thereof.

Clause 21. The electronic device of any of clauses 19 to 20, wherein the inductive device further comprises: a magnetic material disposed at the intermediate layer and between the first array of conductive patterns and the second array of conductive patterns.

Clause 22. The electronic device of clause 21, wherein: the magnetic material comprises carbon, silicon, chromium, iron, platinum, phosphorus, or any combination thereof.

Clause 23. The electronic device of clause 19, wherein: the first interconnect is configured to connect the first conductive structure of the first set of conductive structures disposed at a first end of the first coil structure to the second conductive structure of the second set of conductive structures disposed at a half-turn position of the second coil structure from a second end of the second coil structure corresponding to the first end of the first coil structure, and the inductive device further comprises a second interconnect at the intermediate layer and configured to connect a third conductive structure of the first set of conductive structures disposed at a third end of the first coil structure to a fourth conductive structure of the second set of conductive structures disposed at a half-turn position of the second coil structure from a fourth end of the second coil structure corresponding to the third end of the first coil structure.

Clause 24. The electronic device of clause 23, wherein the inductive device further comprises: a third interconnect at the intermediate layer and configured to connect a fifth conductive structure of the first set of conductive structures disposed at a half-turn position of the first coil structure from the first end of the first coil structure to a sixth conductive structure of the second set of conductive structures disposed at the second end of the second coil structure, and a fourth interconnect at the intermediate layer and configured to connect a seventh conductive structure of the first set of conductive structures disposed at a half-turn position of the first coil structure from the third end of the first coil structure to an eighth conductive structure of the second set of conductive structures disposed at the fourth end of the second coil structure.

Clause 25. The electronic device of clause 24, wherein the inductive device further comprises: a fifth interconnect at the intermediate layer and configured to connect the first conductive structure of the first set of conductive structures disposed at the first end of the first coil structure to the sixth conductive structure of the second set of conductive structures disposed at the second end of the second coil structure, and a sixth interconnect at the intermediate layer and configured to connect the third conductive structure of the first set of conductive structures disposed at the third end of the first coil structure to the eighth conductive structure of the second set of conductive structures disposed at the fourth end of the second coil structure.

Clause 26. The electronic device of clause 19, wherein: the first interconnect is configured to connect the first conductive structure of the first set of conductive structures disposed at a first end of the first coil structure to the second conductive structure of the second set of conductive structures disposed at a second end of the second coil structure corresponding to the first end of the first coil structure, and the inductive device further comprises a second interconnect at the intermediate layer and configured to connect a third conductive structure of the first set of conductive structures disposed at a third end of the first coil structure to a fourth conductive structure of the second set of conductive structures disposed at a fourth end of the second coil structure corresponding to the third end of the first coil structure.

Clause 27. The electronic device of clause 19, wherein: the first interconnect is configured to connect the first conductive structure of the first set of conductive structures disposed at a middle portion of the first coil structure to the second conductive structure of the second set of conductive structures disposed at a middle portion of the second coil structure.

Clause 28. The electronic device of any of clauses 19 to 27, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such. Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

What is claimed is:

1. An inductive device, comprising:
a first array of conductive patterns arranged in parallel at a first metallization layer, the first array of conductive patterns including a first set of conductive patterns and a second set of conductive patterns that are alternatively arranged in the first array;
a second array of conductive patterns arranged in parallel at a second metallization layer, the second array of conductive patterns including a third set of conductive patterns and a fourth set of conductive patterns that are alternatively arranged in the second array;
a first set of conductive structures and a second set of conductive structures at an intermediate layer between the first metallization layer and the second metallization layer,
the first set of conductive structures configured to connect the first set of conductive patterns and the third set of conductive patterns to form a first coil structure of a first inductor of the inductive device, and
the second set of conductive structures configured to connect the second set of conductive patterns and the fourth set of conductive patterns to form a second coil structure of a second inductor of the inductive device; and
a first interconnect at the intermediate layer and configured to connect a first conductive structure of the first set of conductive structures to a second conductive structure of the second set of conductive structures.

2. The inductive device of claim 1, wherein:
the first array of conductive patterns and the second array of conductive patterns comprise a conductive material that includes copper, aluminum, gold, or a combination thereof, and
the first set of conductive structures and the second set of conductive structures comprise a conductive material that includes copper, aluminum, gold, or a combination thereof.

3. The inductive device of claim 1, further comprising:
a magnetic material disposed at the intermediate layer and between the first array of conductive patterns and the second array of conductive patterns.

4. The inductive device of claim 3, wherein:
the magnetic material comprises carbon, silicon, chromium, iron, platinum, phosphorus, or any combination thereof.

5. The inductive device of claim 1, wherein:
the first interconnect is configured to connect
the first conductive structure of the first set of conductive structures disposed at a first end of the first coil structure to
the second conductive structure of the second set of conductive structures disposed at a half-turn position of the second coil structure from a second end of the second coil structure corresponding to the first end of the first coil structure, and
the inductive device further comprises a second interconnect at the intermediate layer and configured to connect
a third conductive structure of the first set of conductive structures disposed at a third end of the first coil structure to
a fourth conductive structure of the second set of conductive structures disposed at a half-turn position of the second coil structure from a fourth end of the second coil structure corresponding to the third end of the first coil structure.

6. The inductive device of claim 5, further comprising:
a third interconnect at the intermediate layer and configured to connect
a fifth conductive structure of the first set of conductive structures disposed at a half-turn position of the first coil structure from the first end of the first coil structure to
a sixth conductive structure of the second set of conductive structures disposed at the second end of the second coil structure, and
a fourth interconnect at the intermediate layer and configured to connect
a seventh conductive structure of the first set of conductive structures disposed at a half-turn position of the first coil structure from the third end of the first coil structure to
an eighth conductive structure of the second set of conductive structures disposed at the fourth end of the second coil structure.

7. The inductive device of claim 6, further comprising:
a fifth interconnect at the intermediate layer and configured to connect
the first conductive structure of the first set of conductive structures disposed at the first end of the first coil structure to
the sixth conductive structure of the second set of conductive structures disposed at the second end of the second coil structure, and
a sixth interconnect at the intermediate layer and configured to connect
the third conductive structure of the first set of conductive structures disposed at the third end of the first coil structure to
the eighth conductive structure of the second set of conductive structures disposed at the fourth end of the second coil structure.

8. The inductive device of claim 1, wherein:
the first interconnect is configured to connect
the first conductive structure of the first set of conductive structures disposed at a first end of the first coil structure to
the second conductive structure of the second set of conductive structures disposed at a second end of the second coil structure corresponding to the first end of the first coil structure, and
the inductive device further comprises a second interconnect at the intermediate layer and configured to connect
a third conductive structure of the first set of conductive structures disposed at a third end of the first coil structure to
a fourth conductive structure of the second set of conductive structures disposed at a fourth end of the second coil structure corresponding to the third end of the first coil structure.

9. The inductive device of claim 1, wherein:
the first interconnect is configured to connect
the first conductive structure of the first set of conductive structures disposed at a middle portion of the first coil structure to
the second conductive structure of the second set of conductive structures disposed at a middle portion of the second coil structure.

10. A method of manufacturing an inductive device, comprising:
forming a first array of conductive patterns arranged in parallel at a first metallization layer, the first array of conductive patterns including a first set of conductive patterns and a second set of conductive patterns that are alternatively arranged in the first array;
forming a second array of conductive patterns arranged in parallel at a second metallization layer, the second array of conductive patterns including a third set of conductive patterns and a fourth set of conductive patterns that are alternatively arranged in the second array;
forming a first set of conductive structures and a second set of conductive structures at an intermediate layer between the first metallization layer and the second metallization layer,
the first set of conductive structures configured to connect the first set of conductive patterns and the third set of conductive patterns to form a first coil structure of a first inductor of the inductive device, and
the second set of conductive structures configured to connect the second set of conductive patterns and the fourth set of conductive patterns to form a second coil structure of a second inductor of the inductive device; and
forming a first interconnect at the intermediate layer and configured to connect a first conductive structure of the first set of conductive structures to a second conductive structure of the second set of conductive structures.

11. The method of claim 10, wherein:
the first array of conductive patterns and the second array of conductive patterns comprise a material that includes copper, aluminum, gold, or a combination thereof, and
the first set of conductive structures and the second set of conductive structures comprise a material that includes copper, aluminum, gold, or a combination thereof.

12. The method of claim 10, further comprising:
forming a magnetic material disposed at the intermediate layer and between the first array of conductive patterns and the second array of conductive patterns.

13. The method of claim 12, wherein:
the magnetic material comprises carbon, silicon, chromium, iron, platinum, phosphorus, or any combination thereof.

14. The method of claim 10, wherein:
the first interconnect is configured to connect
the first conductive structure of the first set of conductive structures disposed at a first end of the first coil structure to
the second conductive structure of the second set of conductive structures disposed at a half-turn position of the second coil structure from a second end of the second coil structure corresponding to the first end of the first coil structure, and
the method further comprises forming a second interconnect at the intermediate layer, the second interconnect configured to connect
a third conductive structure of the first set of conductive structures disposed at a third end of the first coil structure to
a fourth conductive structure of the second set of conductive structures disposed at a half-turn position of the second coil structure from a fourth end of the second coil structure corresponding to the third end of the first coil structure.

15. The method of claim 14, further comprising:
forming a third interconnect at the intermediate layer, the third interconnect configured to connect
a fifth conductive structure of the first set of conductive structures disposed at a half-turn position of the first coil structure from the first end of the first coil structure to
a sixth conductive structure of the second set of conductive structures disposed at the second end of the second coil structure, and
forming a fourth interconnect at the intermediate layer, the fourth interconnect configured to connect
a seventh conductive structure of the first set of conductive structures disposed at a half-turn position of the first coil structure from the third end of the first coil structure to
an eighth conductive structure of the second set of conductive structures disposed at the fourth end of the second coil structure.

16. The method of claim 15, further comprising:
forming a fifth interconnect at the intermediate layer, the fifth interconnect configured to connect
the first conductive structure of the first set of conductive structures disposed at the first end of the first coil structure to
the sixth conductive structure of the second set of conductive structures disposed at the second end of the second coil structure, and
forming a sixth interconnect at the intermediate layer, the sixth interconnect configured to connect
the third conductive structure of the first set of conductive structures disposed at the third end of the first coil structure to
the eighth conductive structure of the second set of conductive structures disposed at the fourth end of the second coil structure.

17. The method of claim 10, wherein:
the first interconnect is configured to connect
the first conductive structure of the first set of conductive structures disposed at a first end of the first coil structure to
the second conductive structure of the second set of conductive structures disposed at a second end of the second coil structure corresponding to the first end of the first coil structure, and
the method further comprises forming a second interconnect at the intermediate layer, the second interconnect configured to connect
a third conductive structure of the first set of conductive structures disposed at a third end of the first coil structure to
a fourth conductive structure of the second set of conductive structures disposed at a fourth end of the second coil structure corresponding to the third end of the first coil structure.

18. The method of claim 10, wherein:
the first interconnect is configured to connect
the first conductive structure of the first set of conductive structures disposed at a middle portion of the first coil structure to
the second conductive structure of the second set of conductive structures disposed at a middle portion of the second coil structure.

19. An electronic device, comprising:
an inductive device that comprises:
a first array of conductive patterns arranged in parallel at a first metallization layer, the first array of conductive patterns including a first set of conductive patterns and a second set of conductive patterns that are alternatively arranged in the first array;
a second array of conductive patterns arranged in parallel at a second metallization layer, the second array of conductive patterns including a third set of conductive patterns and a fourth set of conductive patterns that are alternatively arranged in the second array;
a first set of conductive structures and a second set of conductive structures at an intermediate layer between the first metallization layer and the second metallization layer,
the first set of conductive structures configured to connect the first set of conductive patterns and the third set of conductive patterns to form a first coil structure of a first inductor of the inductive device, and
the second set of conductive structures configured to connect the second set of conductive patterns and the fourth set of conductive patterns to form a second coil structure of a second inductor of the inductive device; and
a first interconnect at the intermediate layer and configured to connect a first conductive structure of the first set of conductive structures to a second conductive structure of the second set of conductive structures.

20. The electronic device of claim 19,
wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
